(19) United States
(12) Patent Application Publication
(10) Pub. No.: US 2011/0318908 A1
(43) Pub. Date: Dec. 29, 2011

(54) MANUFACTURING METHOD OF SEMICONDUCTOR DEVICE AND SEMICONDUCTOR MANUFACTURING APPARATUS

(75) Inventors: Sho KATO, Isehara (JP); Hidekazu MIYAIRI, Isehara (JP); Akihisa SHIMOMURA, Isehara (JP)

(73) Assignee: SEMICONDUCTOR ENERGY LABORATORY CO., LTD., Atsugi-shi (JP)

(21) Appl. No.: 13/227,146

(22) Filed: Sep. 7, 2011

Related U.S. Application Data
(62) Division of application No. 12/040,934, filed on Mar. 3, 2008.

(30) Foreign Application Priority Data
Mar. 7, 2007 (JP) 2007-057424

(51) Int. Cl. H01L 21/268

(52) U.S. Cl. 438/487; 257/E21.347

(57) ABSTRACT

The present invention is a semiconductor manufacturing apparatus by which an impurity can be introduced into an active layer at a low and a stable concentration in order to form semiconductor elements that have little variation in threshold voltage. In the semiconductor manufacturing apparatus that includes a washing unit; an impurity introduction unit used to attach the impurity to the surface of the semiconductor film; a laser crystallization unit used to crystallize the semiconductor film to which an impurity has been attached; and transfer robots, the amount of the impurity attached to the semiconductor film is controlled by the length of time of exposure of the substrate in the impurity introduction unit, and the semiconductor film is crystallized while a crystalline semiconductor film that contains an impurity at low concentration is formed simultaneously by laser crystallization.

### BACKGROUND OF THE INVENTION

1. Field of the Invention

The present invention relates to manufacturing methods of semiconductor devices such as thin film transistors (hereinafter referred to as TFTs) and the like. In particular, the present invention relates to semiconductor manufacturing apparatuses by which doping processes are performed.

2. Description of the Related Art

In techniques for formation of high performance circuits over conventional substrates using semiconductor films, in order to control the threshold voltage of the semiconductor elements such as TFTs and the like that act as basic structural elements of the high performance circuits, doping is performed. Doping is a process by which an impurity (a dopant) such as arsenic (As), boron (B), phosphorus (P), or the like is introduced into a semiconductor film. For example, a toxic gas such as diborane (B₂H₆) or the like is made to be a plasma in an ion doping apparatus to form boron ions, and the boron ions are accelerated by an electric field and doped into a semiconductor film formed over a substrate. Subsequently, by activation of the impurity that has been introduced, the threshold voltage of a semiconductor element formed using the semiconductor film is controlled.

Moreover, for doping techniques, in addition to the ion doping technique given above, there is a technique that is referred to as laser doping (for an example of this technique, refer to Patent Document 1). In laser doping, in a laser chamber, a dopant gas is made to flow over the surface of a semiconductor film formed over a substrate, and the surface of the semiconductor film is irradiated with a laser beam that has a wavelength in the ultraviolet light region of the electromagnetic spectrum. By this process, the dopant gas over the surface of the semiconductor film is decomposed by a photochemical reaction, the irradiated part of the semiconductor film is locally melted and solidified, and doping with the impurity can be performed.

The laser doping apparatus used in laser doping is different from an ion doping apparatus in that, with a laser doping apparatus, the formation of cracks in the semiconductor film at the time of doping is suppressed, and furthermore, no annealing process is required in order to activate the introduced impurity. It is to be noted that, for a laser oscillator, for example, an excimer laser with a short wavelength is used.

Aside from the doping performed to control the threshold voltage as described above, there is a technique in which impurities are introduced into a source region and a drain region of a semiconductor element and the resistance of the semiconductor element is reduced. For example, by exposure of the source region and drain region of a semiconductor film to a substance that has dopant atoms, the dopant atoms are attached to the semiconductor film, the source region and the drain region are irradiated with a laser beam, and the dopant atoms are introduced into the semiconductor film

### (Patent Document 2).

Patent Document 1: Japanese Published Patent Application No. H6-151344
Patent Document 2: Japanese Published Patent Application No. 2006-269752

### SUMMARY OF THE INVENTION

To control the amount of variation in threshold voltage, extremely strict control of the amount of impurity implanted is being demanded. However, with doping performed using an ion doping apparatus, because control of the amount of impurity introduced is difficult due to fluctuations in the ratio of types of ion of the dopant and the like, there is a large amount of variation in the threshold voltage of fabricated semiconductor elements. Furthermore, ion doping apparatuses are extremely expensive devices. Moreover, because ion doping apparatuses are sheet-fed apparatuses, operating efficiency is extremely poor, as well.

Furthermore, damage is incurred by an activation layer because of doping, and this damage comes to be a reason that the crystallinity of the semiconductor is reduced. There is a method that is used to restore the damage incurred at the time of doping by recrystallization of the semiconductor film with a laser after the semiconductor film is doped. However, because the concentration of impurities needs to be lowered at the time of doping due to the rate of activation of impurities within the semiconductor film by a laser irradiation process being high, controlling the threshold voltage becomes difficult.

Meanwhile, with a semiconductor manufacturing apparatus that uses a laser doping apparatus, the amount of impurity introduced into the semiconductor film fluctuates if the laser irradiation conditions change, and there is a need to keep the laser irradiation conditions constant in order to obtain threshold voltages with little variation, which is caused by fluctuations in the rate of activation within the semiconductor film.

However, keeping laser irradiation conditions constant is difficult, and, in particular, excimer laser apparatuses that are generally used at wavelengths in the ultraviolet light region of the electromagnetic spectrum are extremely unstable devices.

In addition, with laser doping apparatuses, because the impurity gas is decomposed by a photochemical reaction, the coating on the inside of a laser chamber of a quartz window used to introduce the laser beam into the laser chamber might receive damage. Because of this damage, the optical transmission rate of the laser beam declines dramatically, and keeping laser conditions constant becomes difficult.

Furthermore, in recent years, the design rule for TFTs used to form high performance circuits over glass substrates has been shrinking. In order to control short channel effects caused by shortening of the channel length, it is desirable that the surface of the activation layer be evened out and the gate insulating film be made to be thin, that the concentration of impurities in the activation layer be reduced, and that the activation layer be made extremely thin (for example, the film thickness of the activation layer be made to be less than 50 nm). However, keeping the concentration of the impurity in the depth-wise direction of the activation layer uniform has been difficult with conventional ion doping apparatuses, and keeping conditions for laser irradiation of the activation layer stable has been difficult with conventional laser doping apparatuses.

Moreover, when dopant atoms are attached to a source region or a drain region and introduced by laser irradiation, there is no need to accurately control the number of dopant atoms that are attached as long as the number of dopant atoms that are to be introduced at a high concentration can be introduced into the semiconductor film at a concentration above a certain level. For this reason, the number of dopant atoms that are to be attached at a low concentration cannot be controlled, and the amount of variation in the threshold voltage of semiconductor elements fabricated using conventional doping methods cannot be suppressed.

The present invention is formed in consideration of the aforementioned problems, and an object of the present invention is to introduce impurities into an activation layer at low concentration and high precision, in order to provide semiconductor elements that have little variation in threshold voltage.

An object of the semiconductor manufacturing apparatus of the present invention is to provide a crystalline semiconductor film by which a high performance semiconductor element can be fabricated, by control of the amount of the impurity attached to the semiconductor film based on a linear, correlative relationship between the length of time of exposure to an impurity concentration atmosphere and the threshold voltage, and then formation of a crystalline semiconductor film that contains an impurity at a low concentration corresponding to that of channel doping simultaneous with crystallization of the semiconductor film by laser crystallization.

One semiconductor manufacturing apparatus of the present invention is a semiconductor manufacturing apparatus by which impurities are introduced into a semiconductor film provided over an insulating substrate, and the semiconductor manufacturing apparatus has a washing unit used to wash a surface of the semiconductor film; an impurity introduction unit used to attach impurities to the surface of the semiconductor film; and a laser crystallization unit used to irradiate the surface of the semiconductor film to which the impurities have been attached with a laser beam to crystallize the semiconductor film; where transfer robots are connected to each of the washing unit, the impurity introduction unit, and the laser crystallization unit. Furthermore, an impurity atmosphere chamber and an impurity generator used to supply an impurity gas in the impurity atmosphere chamber are provided in the impurity introduction unit.

Moreover, in the semiconductor manufacturing apparatus of the present invention, the insulating substrate that has a semiconductor film is exposed to an impurity atmosphere in the impurity introduction unit, and the amount of impurity that is attached to the semiconductor film is controlled by the length of time of exposure to the impurity atmosphere in the impurity introduction unit.

Another semiconductor manufacturing apparatus of the present invention is a semiconductor manufacturing apparatus that has a washing unit used to wash a surface of a semiconductor film; a film formation unit used to form an oxide film over the semiconductor film; an impurity introduction unit used to attach impurities to the surface of the oxide film; and a laser crystallization unit used to irradiate the oxide film and the semiconductor film to which the impurities have been attached with a laser beam to crystallize the semiconductor film; where transfer robots are connected to each of the washing unit, the film formation unit, the impurity introduction unit, and the laser crystallization unit. Furthermore, an impurity atmosphere chamber and an impurity generator used to supply an impurity gas in the impurity atmosphere chamber are provided in the impurity introduction unit.

A semiconductor manufacturing apparatus of the present invention is a semiconductor manufacturing apparatus that has a washing unit used to wash a surface of the semiconductor film; an impurity introduction unit used to attach impurities to the surface of the semiconductor film; and a laser crystallization unit used to irradiate the semiconductor film to which the impurities have been attached with a laser beam to crystallize the semiconductor film; where transfer robots are connected to each of the washing unit, the impurity introduction unit, and the laser crystallization unit. Furthermore, an impurity atmosphere chamber and an impurity generator used to supply an impurity gas in the impurity atmosphere chamber are provided in the impurity introduction unit. In addition, the impurity atmosphere chamber has wires used to support the insulating substrate; wire holders used to hold the wires in place; support mechanisms used to grasp onto the wire holders in the impurity atmosphere; and drivers used to move the support mechanisms inside the impurity atmosphere chamber up and down. The insulating substrates that are introduced into the impurity introduction unit are transferred to the laser crystallization unit in the order in which they are received.

A method of manufacturing a semiconductor device of the present invention includes the steps of forming a semiconductor film over an insulating substrate; washing the semiconductor film and then transporting the insulating substrate into an impurity atmosphere and attaching an impurity to the surface of the semiconductor film; transporting and mounting the insulating substrate to which the impurity is attached to a stage; irradiating the insulating substrate on the stage with a laser beam that is projected from a laser oscillator; crystallizing the semiconductor film to which the impurity is attached; and forming a crystalline semiconductor film that contains an impurity.

Furthermore, another method of manufacturing a semiconductor device of the present invention includes the steps of forming a semiconductor film over an insulating substrate; washing the semiconductor film and then forming an oxide film over the semiconductor film; transporting the insulating substrate to an impurity atmosphere and attaching an impurity to the semiconductor film through the oxide film; transporting and mounting the insulating substrate to which the impurity is attached to a stage; irradiating the insulating substrate on the stage with a laser beam that is projected from a laser oscillator; crystallizing the semiconductor film to which the impurity is attached; and forming a crystalline semiconductor film that contains an impurity.

With the semiconductor manufacturing apparatus of the present invention, introduction of an impurity into an active layer of a semiconductor element at low concentration and a high level of accuracy can be realized. As a result, the ability to control threshold voltage can be improved, and an even more high performance semiconductor device can be fabricated. Furthermore, because an impurity can be introduced into an active layer of a semiconductor element at low concentration and at a high level of accuracy within a surface of a substrate and between substrates, a high performance semiconductor device can be manufactured at high yield.

### BRIEF DESCRIPTION OF THE DRAWINGS

FIG. 1 is a diagram showing the structure of a semiconductor manufacturing apparatus of the present invention.

FIGS. 2A to 2E are diagrams showing the outline of a crystalline semiconductor film formation process performed using a semiconductor manufacturing apparatus of the present invention.

FIG. 3 is a diagram showing the state of laser irradiation performed using a semiconductor manufacturing apparatus of the present invention.

FIGS. 4A to 4D are diagrams showing the outline of a crystalline semiconductor film formation process performed using a semiconductor manufacturing apparatus of the present invention.

FIGS. 5A and 5B are block diagrams showing the structure of a semiconductor manufacturing apparatus of the present invention.

FIG. 6 is a block diagram showing the structure of a semiconductor manufacturing apparatus of the present invention.

FIG. 7 is a diagram showing the structure of a semiconductor manufacturing apparatus of the present invention.

FIG. 8 is a diagram showing the structure of a semiconductor manufacturing apparatus of the present invention.

FIGS. 9A to 9D are diagrams each showing the structure of components used in a semiconductor manufacturing apparatus of the present invention.

FIGS. 10A to 10C are diagrams each showing the structure of a semiconductor manufacturing apparatus of the present invention.

FIGS. 11A to 11C are diagrams showing the outline of a semiconductor device manufacturing process performed in which a semiconductor manufacturing apparatus of the present invention is used.

FIGS. 12A to 12D are diagrams showing the outline of a semiconductor device manufacturing process performed in which a semiconductor manufacturing apparatus of the present invention is used.

FIGS. 13A to 13C are diagrams showing the outline of a semiconductor device manufacturing process performed in which a semiconductor manufacturing apparatus of the present invention is used.

FIGS. 14A to 14C are diagrams showing the outline of a semiconductor device manufacturing process performed in which a semiconductor manufacturing apparatus of the present invention is used.

FIGS. 15A and 15B are diagrams showing the outline of a semiconductor device manufacturing process performed in which a semiconductor manufacturing apparatus of the present invention is used.

FIGS. 16A to 16C are diagrams showing the outline of a semiconductor device manufacturing process performed in which a semiconductor manufacturing apparatus of the present invention is used.

FIGS. 17A and 17B are diagrams showing the outline of a semiconductor device manufacturing process performed in which a semiconductor manufacturing apparatus of the present invention is used.

FIGS. 18A to 18F are diagrams each showing an outline of an electronic device formed using a semiconductor device of the present invention.

FIGS. 19A and 19B are diagrams each showing an outline of an article formed using a semiconductor device of the present invention.

FIG. 20 is a graph of SIMS analysis results of the concentration of boron introduced into a polycrystalline silicon film that is fabricated using a semiconductor manufacturing apparatus of the present invention.

FIG. 21 is a graph of SIMS analysis results of the concentration of boron introduced into a polycrystalline silicon film that is fabricated using a semiconductor manufacturing apparatus of the present invention.

FIG. 22 is a graph of SIMS analysis results of the concentration of boron introduced into a polycrystalline silicon film that is fabricated using a semiconductor manufacturing apparatus of the present invention.

FIGS. 23A and 23B are graphs of threshold voltage and length of exposure time for exposure in a boron atmosphere and the regression analysis results thereof.

FIG. 24 is a graph of SIMS analysis results of the concentration of boron introduced into a polycrystalline silicon film that is fabricated using a semiconductor manufacturing apparatus of the present invention.

### DETAILED DESCRIPTION OF THE INVENTION

Hereinafter, Embodiment Modes and Embodiments of the present invention will be described based on drawings. However, the present invention can be implemented in a lot of different modes, and it is to be easily understood by those skilled in the art that various changes and modifications can be made without any departure from the spirit and scope of the present invention. Accordingly, the present invention is not to be taken as being limited to the described content of the embodiment modes included herein. It is to be noted that identical portions or portions having similar functions in all figures used to describe embodiment modes are denoted by the same reference numerals, and repetitive description thereof is omitted.

### Embodiment Mode 1

In the present embodiment mode, steps for fabrication of a crystalline semiconductor film that contains an impurity at low concentration over an insulating substrate using a semiconductor manufacturing apparatus of the present invention will be described.

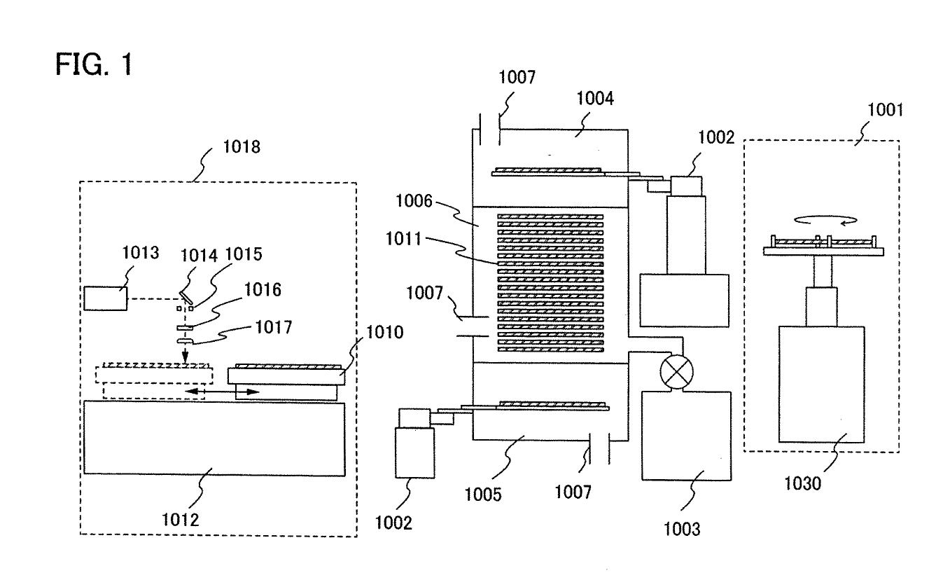

First, using FIG. 1, an example of a semiconductor manufacturing apparatus of the present invention will be described. The semiconductor manufacturing apparatus of the present embodiment mode has a prewashing unit 1001 used to eliminate impurities, an impurity introduction unit, and a laser crystallization unit 1018, and each of the units is connected to transfer robots 1002.

A substrate that is introduced into the semiconductor manufacturing apparatus of the present invention is first washed in the prewashing unit 1001 that is used to eliminate impurities. At this time, impurities which are not needed for doping, for example, an oxide film or the like formed by natural oxidation at the time that the semiconductor film is formed, are removed. It is to be noted that a sheet-fed spin washing machine 1030 is used for a washing machine in FIG. 1; however, the embodiment modes of the present invention are not limited to use of this type of washing machine. For example, a horizontal flow type of washing machine may be used or a batch type of washing machine may be used, as well.

The impurity introduction unit in the present embodiment mode has an impurity generator 1003, an introduction chamber 1004, a discharge chamber 1005, an impurity atmosphere chamber 1006, and exhaust vents 1007. However, the exhaust vents 1007 need not necessarily be formed. Alternatively, the exhaust vents 1007 may be supply and exhaust vents, as well. After a substrate washed in the prewashing unit 1001 that is used to eliminate impurities is introduced into the introduction chamber 1004 by one of the transfer robots 1002, the substrate is transported to the impurity atmosphere chamber 1006. Then, the substrate is exposed to the impurity atmosphere for only the amount of time needed for the impurity to be attached to the surface at the desired concentration and then transported to the laser irradiation unit 1018 by one of the transfer robots 1002 via the discharge chamber 1005.

It is to be noted that, in the impurity atmosphere chamber 1006, while the substrate is being exposed to the impurity atmosphere, other substrates are being transferred into the impurity atmosphere chamber 1006; by the interval between starting times for exposure of each substrate being made to be roughly equal to the length of operating time for the laser crystallization unit, the transport timing for each substrate may be adjusted so that the production efficiency of the impurity introduction unit is not rate-limited. For example, with the operating time of the prewashing unit that is used to eliminate impurities set to t₀, the exposure starting time of the first substrate set to t₁, and the exposure starting time of the second and subsequent substrate set to tₙ (n≧2), the interval Δt between the exposure starting times of each substrate is represented by

Δt=tₙ₊₁−tₙ(n≧2). Formula 1

In addition, if the operating time for the laser crystallization process is set to be T, the transport timing should be controlled so that Δt comes to be T, or Δt=T. However, because the minimum value of Δt is equal to the operating time t₀ in the prewashing unit 1001 that is used to eliminate impurities, when T≦t₀, the operating time of the semiconductor manufacturing apparatus of the present invention is rate-limited by the prewashing unit 1001 that is used to eliminate impurities. In this case, if more of the prewashing units 1001 that are used to eliminate impurities are added, productivity can be increased.

Furthermore, productivity can be increased if more laser crystallization apparatuses are added in the case where the length of the time that a substrate is exposed to the impurity atmosphere is short enough compared to the operating time of the laser crystallization unit. In addition, productivity may also be increased by lowering the impurity concentration of the atmosphere so that the exposure time becomes longer. It is to be noted that, when the length of the exposure time is increased, in order to maintain productivity, because there is a need to increase the number of substrates that are exposed at one time, space used to stock a plurality of substrates in the impurity introduction chamber becomes necessary. By reducing the size of the stock space to a minimum, equipment costs can be reduced.

Next, the laser crystallization unit 1018 will be described. In the present embodiment mode, the laser crystallization unit 1018 has a laser oscillator 1013, an incident light mirror 1014, a slit 1015, a major axis cylindrical lens 1016, a minor axis cylindrical lens 1017, and stages 1010 and 1012. In addition, the substrate that is transported from the impurity introduction unit is placed onto the stage 1010. However, the present invention is not to be taken as being limited to this structure; for example, the slit 1015 and the incident light mirror 1014 need not necessarily be provided. Furthermore, in exchange for the major axis cylindrical lens 1016 and the minor axis cylindrical lens 1017, an optical element such as a spherical lens, an aspherical lens, an aspherical cylindrical lens, an exposure lens, a diffractive optical element, a light pipe, a homogenizer, a fly's eye lens, a cylindrical lens array, or the like or a combination of any of these may be used, as well. Moreover, in order to increase the size of the laser beam projected from the laser oscillator 1013, a beam expander can be used. In order to change the intensity of the laser beam, an attenuator can be used.

The laser beam projected from the laser oscillator 1013 is bent in a direction perpendicular to the substrate on the stage 1010 by the incident light mirror 1014 and passes through the slit 1015, and the part of the laser beam that has weak energy density is blocked. Subsequently, the laser beam passes through the major axis cylindrical lens 1016, and an image is passed through the slit 1015 to the surface that is to be irradiated. Furthermore, the laser beam passes through the minor axis cylindrical lens 1017 and is focused along the minor axis and formed into a linear laser beam, the substrate placed on the stage 1010 is scanned, and laser crystallization is performed.

It is to be noted that, when the width of the major axis of the laser beam is short, the laser beam may be used to scan along a direction perpendicular to the surface that is scanned. Alternatively, the stage 1010 may be used to scan in a direction perpendicular to the surface that is scanned. In addition, a O-axis system and an alignment camera may be provided in the stage 1010 to obtain the alignment of the laser beam scanning direction and the substrate on the stage 1010. Furthermore, a Z-axis system may be provided in the stage 1010 and a mechanism put into place so that the surface that is irradiated is not shifted from the depth of focus in the surface that is to be irradiated by the laser beam. Moreover, a plurality of laser oscillators may be prepared and laser crystallization may be performed by use of a plurality of laser beams at the same time, or a plurality of laser beams each with a different wavelength may be combined together to form a single laser beam and laser crystallization may be performed by use of the one laser beam. Additionally, laser crystallization may also be performed using a combination of any of these laser beams.

It is to be noted that a linear laser beam is a laser beam by which the shape of the surface that is irradiated is linear. Here, “linear” does not refer to the strict meaning of “having the shape of a line” but rather to the case where the aspect ratio forms a large rectangular shape (for example, a case where the aspect ratio is 10 or more (preferably, 100 or more)). It is to be noted that setting the laser beam to be linear is done in order to maintain a high enough energy density for adequate performance of laser treatment on the object that is to be irradiated, but the laser beam may also be set to be rectangular or elliptical, as well, as long as an adequate amount of laser treatment can be performed on the object that is to be irradiated using the rectangular or elliptical laser beam.

It is to be noted that, in FIG. 1, spaces other than that of the impurity introduction unit are set to have a structure with a combination of a chemical filter and an impurity-less filter in order to prevent the attachment of impurities to the substrate. In particular, in the case where impurities are scattered throughout the laser crystallization unit 1018, because the laser beam does not have enough energy for the entire surface of the substrate to be laser crystallized all at once, differences in the length of time during which the surface of the substrate is exposed to the impurity develop. When these differences develop, differences in the amount of impurity introduced into the substrate arise, and, as a result, the amount of surface variation in threshold voltage increases, which results in a decrease in yield. Consequently, in the impurity introduction unit, after the substrate is exposed to the impurity atmosphere of low concentration for a constant length of time and the desired impurity is attached to the substrate, that the structure be one in which the amount of purity attached to the substrate is not changed becomes mandatory.

Next, steps for fabrication of a crystalline semiconductor film that contains an impurity at low concentration using the semiconductor manufacturing apparatus shown in FIG. 1 will be described.

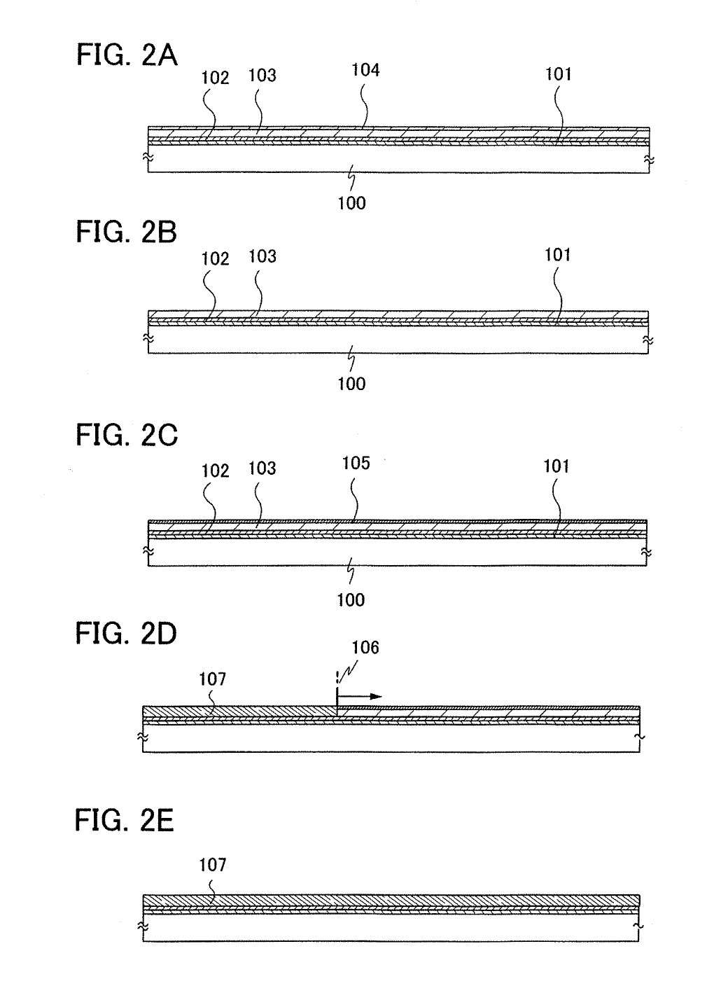

First, a step will be described in which a semiconductor film is formed over an insulating substrate. As illustrated in FIGS. 2A to 2E, over one surface of a substrate 100 that has an insulating surface, a base insulating film is formed. For a method of formation of the base insulating film, a method such as a CVD method, typified by a plasma CVD method or a low-pressure CVD method; a sputtering method; or the like may be used. Furthermore, for the substrate 100, a glass substrate formed of barium borosilicate glass, alumino-borosilicate glass, or the like; a quartz substrate; a ceramic substrate; or the like can be used. A substrate that is formed of a flexible synthetic resin such as a plastic has a tendency to have relatively low heat resistance, in general, compared to the substrates given above but can be used as long as it is a substrate that is able to withstand the process temperatures of the fabrication steps. In other words, a plastic substrate that has resistance to heat can also be used for the substrate 100.

The base insulating film may be set to have a single-layer structure using any of a silicon oxide film, a silicon nitride film, a silicon oxynitride film, or a silicon nitride oxide film or a structure in which any of these films are stacked together as appropriate. It is to be noted that, in the present specification, “silicon oxynitride” refers to a substance in which the composition ratio of oxygen is higher than that of nitrogen and can also be used to refer to a silicon oxide that contains nitrogen. In addition, in the present specification, “silicon nitride oxide” refers to a substance in which the composition ratio of nitrogen is higher than that of oxygen and can also be used to refer to a silicon nitride that contains oxygen. In the present embodiment mode, the base insulating film is set to have a stacked-layer structure of a silicon nitride film 101 that has a film thickness of from 30 nm to 150 nm and a silicon oxide film 102 that has a film thickness of from 20 nm to 150 nm which are stacked together in the order given.

Next, over the base insulating film, an amorphous semiconductor film, formed at a film thickness of from 2 nm to 100 nm, preferably, at a film thickness of from 20 nm to 70 nm, is formed as a semiconductor film 103. For a method of formation of the semiconductor film 103, as with the base insulating film, a method such as a CVD method, a sputtering method, or the like may be used.

It is to be noted that the base insulating film, which is used to function as a blocking film in order to prevent the diffusion of impurities, may be provided according to need. When the substrate 100 is a glass substrate that contains impurities, in particular, mobile ions that easily move around, the base insulating layer is used to prevent the diffusion of impurities from the glass into the semiconductor film 103. However, in the case where a quartz substrate is used for the substrate 100, there is no need to provide a base insulating layer that is used to function as a blocking layer.

It is to be noted that a silicon nitride film has more blocking capability for the prevention of impurity diffusion from glass than a silicon oxide film. On the other hand, fewer interface states are generated in the interface of a base insulating film formed in contact with the semiconductor film 103 with a silicon oxide film than with a silicon nitride film. As a consequence, for the structure of the base insulating film, it is preferable that the base insulating film formed in contact with the substrate side be a silicon nitride film and the base insulating film formed in contact with the semiconductor film 103 be a silicon oxide film. The reason for this is that, when a TFT in which a silicon nitride film is formed in contact with the semiconductor film and an interface state is generated therebetween is fabricated, charge is trapped in the interface between the base insulating film and the semiconductor film, and there are wide fluctuations in threshold voltage due to the effects on electric field by the trapped charge.

Furthermore, the structure may be one in which a separation layer is provided between the base insulating film and the substrate 100 and the semiconductor element is separated from the substrate 100 after completion of the semiconductor element fabrication steps. It is to be noted that, for a separation layer, for example, a silicon oxynitride film with a thickness of from 50 nm to 200 nm is formed over the substrate 100 as the base insulating film by a plasma CVD method. Then, a tungsten film with a thickness of from 10 nm to 100 nm is formed over the base insulating film as a metal film by a sputtering method. Moreover, a silicon oxide film with a thickness of from 50 nm to 400 nm is formed over the metal film as an insulating film by a sputtering method. A film of a plurality of layers formed in this way is used for the separation layer. It is to be noted that the interface at which separation occurs is the interface between the metal film and the insulating film.

It is to be noted that amorphous silicon is used for the semiconductor film 103 in the present embodiment mode; however, polycrystalline silicon may also be used. For example, after formation of the amorphous silicon film, a polycrystalline silicon film can be formed by the addition of trace amounts of an element such as nickel, palladium, germanium, iron, aluminum, tin, zinc, cobalt, platinum, copper, gold, or the like to the amorphous silicon film and the performance of heat treatment at 650° C. for 6 minutes thereafter. Alternatively, silicon germanium or the like may be used instead of the amorphous silicon; furthermore, single-crystal silicon carbide (SiC), which has a diamond structure, can be used. In addition, any of these films may be stacked together as appropriate, as well.

Moreover, after the amorphous silicon film is formed for the semiconductor film 103, the semiconductor film 103 may be heated in an electric furnace at 500° C. for one hour in order to remove hydrogen from the amorphous silicon film. It is to be noted that the removal of hydrogen is performed in order to prevent bumping of hydrogen gas in the semiconductor film 103 at the time that the semiconductor film 103 is irradiated with a laser beam and ablation of the semiconductor film 103. However, if the amount of hydrogen contained in the semiconductor film 103 is low, this step may be omitted.

It is to be noted that a silicon oxide film is formed on the surface of the semiconductor film 103 by natural oxidation at the time that the semiconductor film 103 is formed; at the time that hydrogen is removed from the semiconductor film 103, by heat treatment; or during the time that the substrate is transported after the semiconductor film 103 is formed, by exposure to a clean room (hereinafter, CR) atmosphere. Furthermore, an oxidized film layer 104 is formed over the silicon oxide film by attachment of an organic substance, an impurity, or the like at the time of exposure to the CR atmosphere (FIG. 2A). Because the film thickness and film uniformity of the oxidized film layer 104 are not known, the oxidized film layer 104 is removed during a subsequent step.

Next, a step for introduction of an impurity into the semiconductor film 103 at a desired concentration, in order to control threshold voltage, using the semiconductor manufacturing apparatus of the present invention will be described.

First, by the steps described above, the substrate 100 over which is provided the semiconductor film 103 is transported to the prewashing unit 1001 that is used to eliminate impurities of the semiconductor fabrication apparatus shown in FIG. 1. In the prewashing unit 1001, after impurities, such as the oxidized film layer 104 and the like that are described above, not needed for doping are removed by the sheet-fed spin washing machine and the semiconductor film 103 is exposed, the substrate 100 over which is provided the semiconductor film 103 is spun dry (FIG. 2B).

The substrate 100 from which impurities not needed for doping are removed is transported to the impurity atmosphere chamber 1006 and exposed to the impurity atmosphere of low concentration for only the length of time required for the impurity to be attached at the desired concentration. Accordingly, as shown in FIG. 2C, an impurity 105 of the desired concentration can be attached to the semiconductor film 103.

Next, in the laser crystallization unit, as shown in FIG. 2D, by irradiation of the semiconductor film 103 with a laser beam 106, the semiconductor film 103 is melted, and, at the same time, the impurity 105 is dispersed throughout the melted semiconductor film 103. After irradiation with the laser beam 106, heat is diffused from the melted semiconductor film 103, the semiconductor film 103 is crystallized by cooling, and a crystalline semiconductor film 107 that contains an impurity of low concentration at an approximately uniform concentration is formed (FIG. 2E). It is to be noted that, in the present embodiment mode, an impurity of low concentration refers to when the concentration of impurity included in a region of the crystalline semiconductor film corresponding to a channel formation region of a TFT is at a concentration within the range of from 1×10¹⁵ atoms/cm³ to 1×10¹⁸ atoms/cm³.

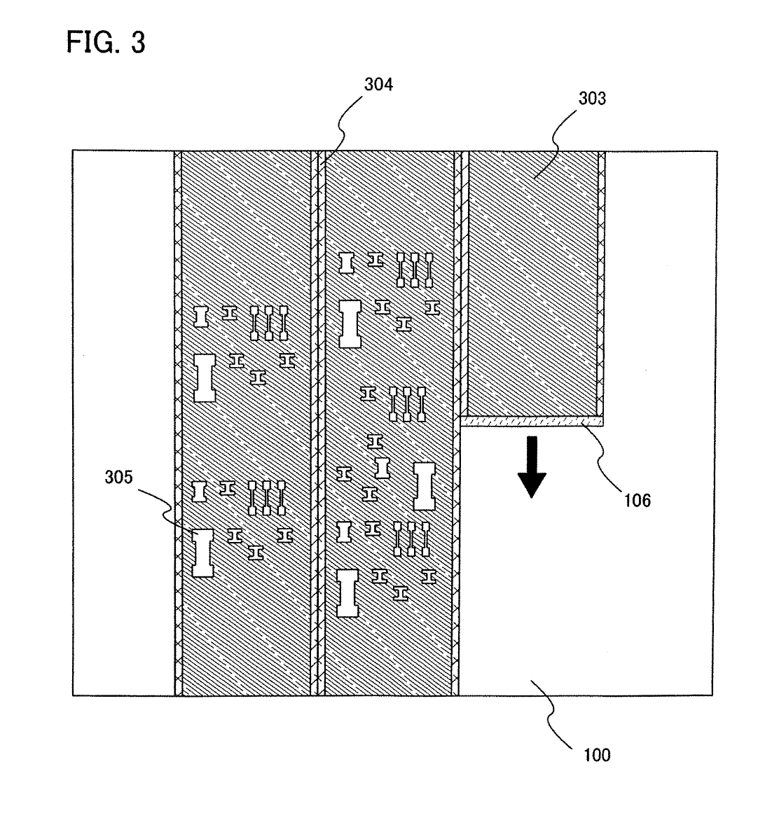

In FIG. 3, a top-view diagram of a laser crystallization process of the present embodiment mode is shown. In the present embodiment mode, a linear laser beam 106 approximately 500 μm by 20 μm is formed using a quasi-continuous wave laser (YVO₄, second harmonic (532 nm), 80 MHz, 20 W) as a laser oscillator and using a slit and two cylindrical lenses. The laser power on the irradiated surface is set to be from 10 W to 20 W, the substrate 100 is irradiated with the laser beam 106 while being scanned by the laser beam 106 at a constant speed of 350 mm/s in a direction perpendicular to the major axis of the laser beam 106, a laser crystallized region 303 with a width of 500 μm is formed, the substrate 100 is moved at a pitch of 500 μm in a direction parallel to the major axis of the laser beam 106, and regions used to form semiconductor elements are laser crystallized.

It is to be noted that, for the scanning direction of the laser beam, for example, the laser beam may be used to scan in one direction, or the scanning direction may differ by 180° alternatingly in adjacent laser crystallized regions 303. Furthermore, the repetition rate of the quasi-continuous wave laser is not limited to being 80 MHz, and a laser oscillator that oscillates at a repetition rate of 10 MHz or more, for example, may be used.

In addition, in the present embodiment mode, a quasi-continuous wave laser is used for the laser oscillator. However, the laser oscillator is not limited to being a quasi-continuous wave laser, and a pulsed laser may be used or a continuous wave laser may be used. Here, for a laser beam that can be pulse-oscillated, an Ar laser, a Kr laser, an excimer laser, a CO₂ laser, a YAG laser, a Y₂O₃ laser, a YVO₄ laser, a GdVO₄ laser, a YLF laser, a YAlO₃ laser, a glass laser, a ruby laser, an alexandrite laser, a Ti:sapphire laser, a copper vapor laser, a gold vapor laser, or the like can be used. Furthermore, for a laser beam that can be oscillated continuously, a gas laser or a solid-state laser can be used. For a gas laser, there is an Ar laser, a Kr laser, and the like. In addition, for a solid-state laser, a laser that uses a crystal such as YAG, YVO₄, YLF, YAlO₃, Y₂O₃, GdVO₄, or the like, which is doped with Cr, Nd, Er, Ho, Ce, Co, Ti, Yb, or Tm, or the like can be used. The fundamental waves of solid-state lasers differ depending on the material with which the laser is doped, and a laser beam with a fundamental wave of about 1 μm can be obtained. The harmonics of the fundamental wave can be obtained by use of a non-linear optical element.

Moreover, in the present embodiment mode, a linear laser beam with a width of approximately 500 μm in the direction of the major axis is formed with the output of the laser oscillator being 20 W; however, the beam width in the direction of the major axis is not to be limited to being 500 μm. For example, if a laser of a laser oscillator that has a greater output is used, a linear laser beam with a width greater than or equal to 500 μm can be formed. Furthermore, the same is true in the case where the light use efficiency in an optical system is increased. In addition, in the present embodiment mode, the optimal value of the substrate scanning speed is set to be 350 mm/s. However, because the optimal value is determined by the rate of change of optical constants, thermal conductivity of a bottom layer of the semiconductor film, laser oscillation output, laser repetition rate, transmittance of an optical system, shape of the beam on the irradiated surface, stability of constant velocity of the stage, device operating efficiency, and the like along with film thickness of the amorphous semiconductor film, absorptivity of the amorphous semiconductor film, and phase change of the semiconductor film, the substrate scanning speed is not limited to being 350 mm/s, and the optimal value may be set in each condition.

It is to be noted that both edges of the laser crystallized regions 303 have regions 304 that have poor crystallinity. If a semiconductor element pattern 305 is formed in one of the regions 304, because variations in the electrical characteristics of the semiconductor elements occur due to differences in crystallinity, it is preferable that the semiconductor element pattern 305 be placed inside the laser crystallized region 303.

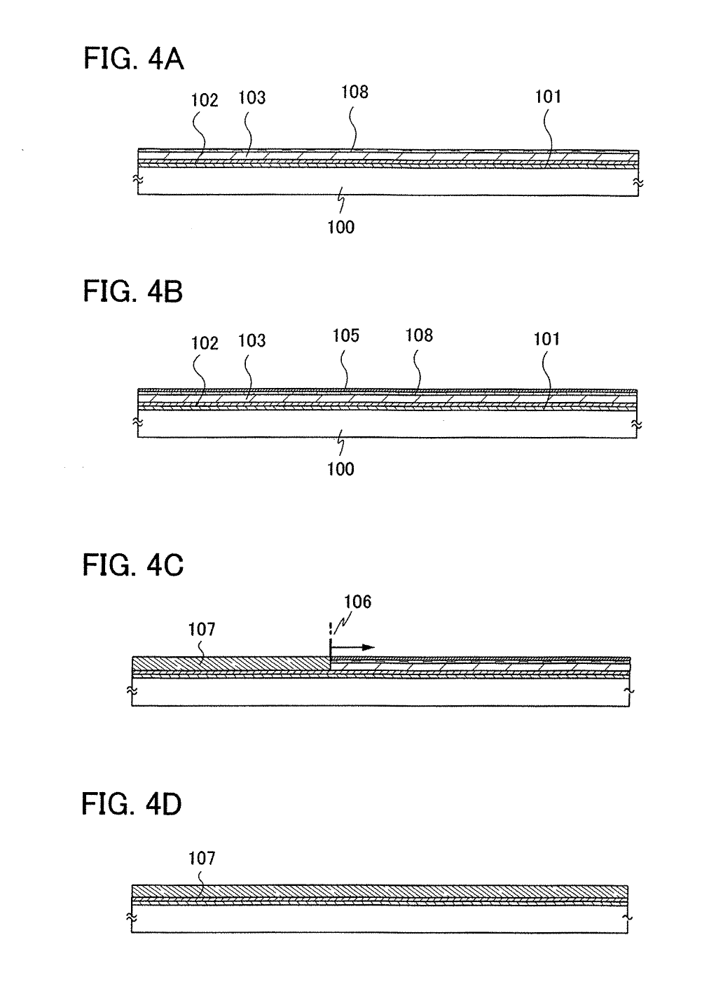

It is to be noted that, in the steps described above for fabrication of the crystalline semiconductor film that contains an impurity, after the silicon nitride film 101, the silicon oxide film 102, and the semiconductor film 103 are formed over the substrate 100 as shown in FIG. 2A, the oxidized film layer 104 formed over the semiconductor film 103 is removed in the prewashing unit used to eliminate impurities because the film thickness and film uniformity of the oxidized film layer 104 is unclear. However, after the oxidized film layer is removed in the prewashing unit used to eliminate impurities, an oxide film 108 may be formed using an aqueous solution that contains ozone, as shown in FIG. 4A. In washing of the semiconductor film after removal of the oxidized film layer 104 from the surface of the semiconductor film, the exposed semiconductor film reacts with oxygen in the atmosphere and H₂O molecules of pure water that is used for washing, and a reaction product (referred to as a watermark) is produced over the semiconductor film. However, generation of a watermark after removal of the oxidized film layer 104 can be prevented by formation of the oxide film 108. Formation of the oxide film 108 may be performed in the prewashing unit that is used to eliminate impurities, or a fabrication unit used for film formation of oxide films may be provided in the semiconductor manufacturing apparatus and the oxide film 108 formed in that unit. It is to be noted that it is preferable that the film thickness of the oxide film 108 be 10 nm or less. After the oxide film 108 is formed, the substrate is exposed to the impurity atmosphere inside the impurity atmosphere chamber 1006, and the impurity 105 of low concentration is attached onto the oxide film 108 (FIG. 4B). Because the oxide film 108 is extremely thin, the semiconductor film can be crystallized by laser crystallization in the same way as that shown in FIG. 2D (FIG. 4C) and the crystalline semiconductor film 107 that contains an impurity of low concentration can be formed (FIG. 4D).

Next, a resist is applied over the crystalline semiconductor film 107, and the resist is exposed to light and developed, whereby a resist pattern of a desired shape is formed. Furthermore, etching is performed using the resist pattern formed here as a mask, and the crystalline semiconductor film 107 that is exposed by development is removed as selected. By this step, island-shaped semiconductor films are formed, and a semiconductor device that has a semiconductor element such as a thin film transistor, a diode, a resistive element, a capacitive element, a CCD, a nonvolatile memory element, or the like can be fabricated using these island-shaped semiconductor films.

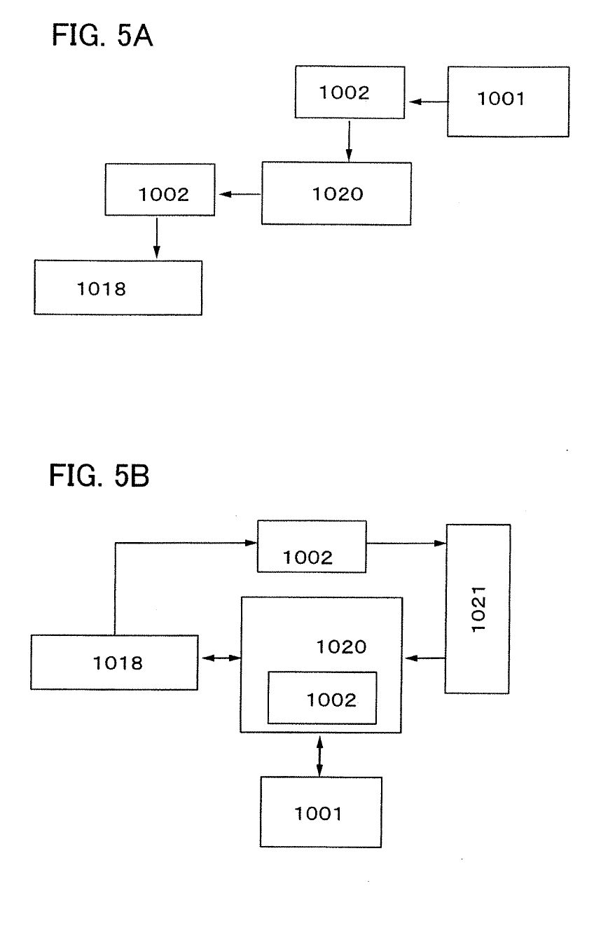

In FIG. 5A, a block diagram of the semiconductor manufacturing apparatus given in FIG. 1 is shown. In the present embodiment mode, as shown in FIG. 5A, a semiconductor manufacturing apparatus that has one of each of the prewashing unit 1001 used to eliminate impurities, an impurity introduction unit 1020, and the laser crystallization unit 1018, where each of the transfer robots 1002 is connected to two of these units, is given; however, the present embodiment mode of the present invention is not limited to having this structure. For example, as shown in FIG. 5B, one of the transfer robots 1002 may be placed within the impurity introduction unit 1020, and the prewashing unit 1001 that is used to eliminate impurities, the impurity introduction unit 1020, and the laser crystallization unit 1018 may be connected together. Furthermore, the substrate that is transported to the prewashing unit 1001 that is used to eliminate impurities may be kept in a cassette station unit 1021. The substrate that is kept in the cassette station unit 1021 is transported to the prewashing unit 1001 that is used to eliminate impurities by the transfer robot 1002 within the impurity introduction unit 1020.

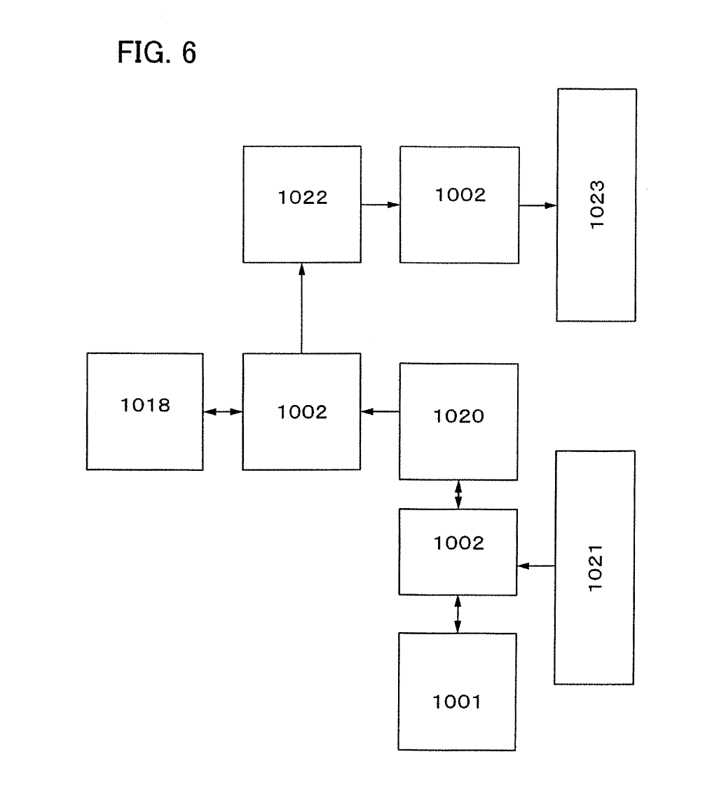

Furthermore, in addition to the structure given in the present embodiment mode, a structure that includes a unit that has other functions may be used, as well. For example, a structure that includes an inspection unit 1022 as shown in FIG. 6 may be used. Here, in FIG. 6, a block diagram of an apparatus that includes the inspection unit 1022 and cassette station units 1021 and 1023 in addition to the structure shown in FIG. 5A is shown. Using the device shown in FIG. 6, a substrate that has a semiconductor film is transported from the cassette station unit 1021 to the prewashing unit 1001 that is used to eliminate impurities via one of the transfer robots 1002, and an oxidized film layer formed over the semiconductor film is removed. Next, the substrate is transported to the impurity introduction unit 1020 via one of the transfer robots 1002, and an impurity is attached onto the semiconductor film. Then, the substrate is transported to the laser crystallization unit 1018 by one of the transfer robots 1002, and the semiconductor film is crystallized so that a crystalline semiconductor film that contains an impurity is formed. The substrate that has the semiconductor film that has been crystallized in the laser crystallization unit 1018 may be inspected by the inspection unit 1022 and held in the cassette station unit 1023. Furthermore, the number of units for each unit may be increased by an appropriate number, which depends on the process efficiency of each unit, so that the efficiency of the entire apparatus is optimized. It is to be noted that the placement of each unit is not limited to that shown as the configuration of FIGS. 5A and 5B but may be optimized in accordance with operating efficiency, costs, installation area of the device (device footprint), space in the clean room, and the like.

By use of the semiconductor manufacturing apparatus of the present invention, an impurity can be introduced into a semiconductor film at low concentration and at a high level of accuracy. Furthermore, because no expensive doping apparatus is used in the introduction of the impurity into the semiconductor film, it becomes possible to provide semiconductor devices at low cost. In addition, by separation of functions into that of the laser crystallization unit and that of the impurity introduction unit, the length of time for exposure of the surface of the substrate to the impurity atmosphere can be set to be constant. For this reason, while process conditions for the laser crystallization process are held stable, there is no reduction in productivity, and the amount of variation in the amount of impurity introduced into a surface of a substrate and between substrates can be greatly decreased. As a result, variations in threshold voltage of semiconductor devices formed by use of these semiconductor films can be suppressed, and high performance semiconductor devices can be fabricated at high productivity and high yield.

Moreover, because the semiconductor manufacturing apparatus of the present invention is a low-cost, simple device in which the impurity introduction unit is simplified structurally and because initial costs can be decreased substantially and running costs can also be decreased substantially due to dramatic improvements in maintenance, semiconductor devices can be manufactured at low cost. In addition, by separation of each unit of the semiconductor manufacturing apparatus of the present invention on a unit-to-unit basis, productivity can easily be optimized.

### Embodiment Mode 2

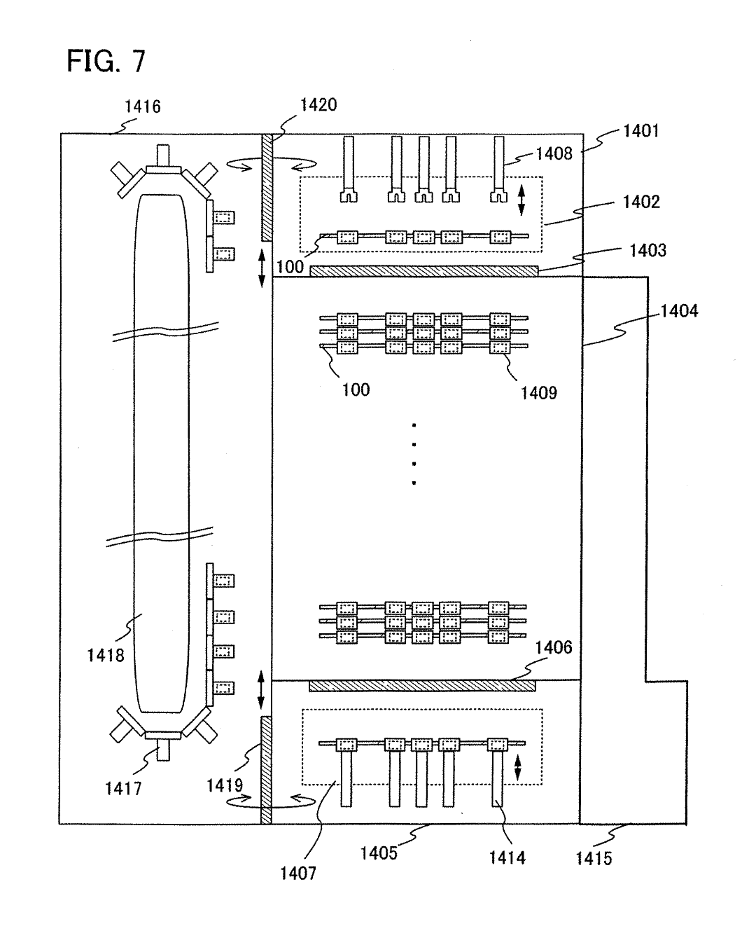

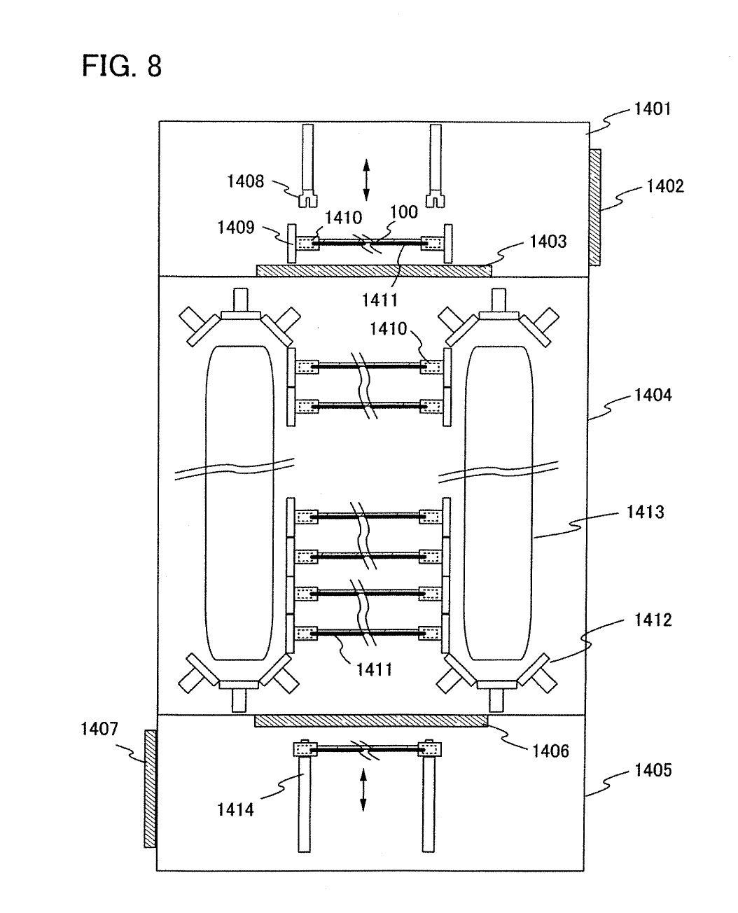

In the present embodiment mode, an example of a structure of an impurity introduction unit of a semiconductor manufacturing apparatus of the present invention will be described using FIG. 7 and FIG. 8. It is to be noted that a top-view diagram of the impurity introduction unit given in the present embodiment mode is shown in FIG. 7 and a side-view diagram thereof in FIG. 8.

The impurity introduction unit shown in FIG. 7 and FIG. 8 has an introduction chamber 1401, an impurity atmosphere chamber 1404, a discharge chamber 1405, a transport driving bay 1416, and an impurity generator 1415. After being washed in the prewashing unit that is used to eliminate impurities, the substrate 100 that has the base insulating film and the semiconductor film is transported to the introduction chamber 1401 through a part 1402 that opens and closes and is mounted onto the wire 1411 (FIG. 8). It is to be noted that, for a method used to form the base insulating film and the semiconductor film over the substrate 100, the same method as the method given in Embodiment Mode 1 can be used. Furthermore, as shown in FIG. 4A, an oxide film may be provided anew over the semiconductor film that is formed over the substrate 100 after the oxidized film layer is removed.

The wire 1411 is held in place by a wire holder 1410 on each side. Furthermore, in the introduction chamber 1401, the wire holder 1410 is supported by support mechanisms 1409. Consequently, the substrate 100 is indirectly supported by the support mechanism 1409 in the introduction chamber 1401.

In transfer of the substrate 100 that is supported by the support mechanisms 1409 from the introduction chamber 1401 to the impurity atmosphere chamber 1404, after the wire holders 1410 are grasped onto by gripper arms 1408, the wire holders 1410 are disconnected from the support mechanisms 1409. This allows the wire holders 1410 to be supported by the gripper arms 1408. Then, the gripper arms 1408 are made to move downward, and the substrate 100 is introduced into the impurity atmosphere chamber 1404 through a part 1403 that opens and closes.

In the impurity atmosphere chamber 1404, each wire holder 1410 is supported by any one of a plurality of support mechanisms 1412 that are provided in the impurity atmosphere chamber 1404 and separated from the gripper arm 1408. Here, the substrate 100 is indirectly supported by the support mechanisms 1412 that are provided in the impurity atmosphere chamber 1404, and the substrate 100 comes to be transported along to the impurity atmosphere chamber 1404. It is to be noted that the support mechanism 1412 is rotated within the impurity atmosphere chamber 1404 in an up and down direction by a driver 1413. In addition, the gripper arms 1208 are removed to the introduction chamber 1401 after being separated from the substrate 100. By the driver 1413 rotating in an up and down direction, the substrate that is transported along moves down in the impurity atmosphere chamber 1404. Moreover, the support mechanisms 1412 that are not supporting a substrate are prepared in sequence for acceptance of a substrate that is transferred from the introduction chamber 1401.

By being made to move down within the impurity atmosphere chamber 1404, the substrate 100 is exposed to the impurity atmosphere for a given length of time, and an impurity is attached to the surface of the semiconductor film at a desired concentration. It is to be noted that, in the present embodiment mode, an element belonging to group 13 or group 15 of the periodic table of the elements or a compound thereof may be used for the impurity; for example, an element such as boron (B), phosphorus (P), arsenic (As), or the like or a compound thereof may be used.

After the impurity is attached to the surface of the semiconductor film, the substrate 100 is moved from the impurity atmosphere chamber 1404 to the discharge chamber 1405 through a part 1406 that opens and closes. Here, for a specific movement method, first, support arms 1414 that are provided in the discharge chamber 1405 are moved upward to the impurity atmosphere chamber 1404 through the part 1406 that opens and closes. Then, after the wire holders 1410 are supported by the support arms 1414, the wire holders 1410 are disconnected from the support mechanisms 1412. Accordingly, the wire holders 1410 can be supported by the support arms 1414. Next, by the support arms being made to move down, the substrate is transferred to the discharge chamber 1405 through the part 1406 that opens and closes.

The substrate that is transported to the discharge chamber 1405 in this way is transported through a part 1407 that opens and closes to the laser crystallization unit of the semiconductor manufacturing apparatus of the present invention by a transfer robot. With the impurity introduction unit of the present embodiment mode, first-in first-out is realized in which the substrates 100 are transported in order starting with the first to enter the introduction chamber 1401 so as to be transported from the discharge chamber 1405 to the laser crystallization unit after being exposed to the impurity atmosphere, and the length of time of exposure for each substrate to the impurity atmosphere can be controlled.

It is to be noted that the wire 1411 and wire holders 1410 that are being supported by the support arms 1414 are moved to the transport driving bay 1416 through a part 1419 that opens and closes after the substrate is discharged to the laser crystallization unit. In the transport driving bay 1416, the wire holders 1410 are supported by support mechanisms 1417 and released from the support arms 1414. It is to be noted that the support mechanisms 1417 are rotated within the transport driving bay 1416 in an up and down direction by a driver 1418. Furthermore, the support arms 1414 from which the wire holders 1410 have been released are removed to the discharge chamber 1405. The wire holders 1410 that are gripped by the support mechanisms 1417 are moved upward by the driver 1418. Next, the wire holders 1410 are again grasped onto by the gripper arms 1408 that have moved from the introduction chamber 1401 through a part 1420 that opens and closes, released from the support mechanisms 1417, and moved to the introduction chamber 1401 through the part 1420 that opens and closes.

It is to be noted that, because each side of the wire 1411 is held in place by one of a pair of the wire holders 1410, there are cases where one of the gripper arms 1408 physically interferes with another gripper arm 1408 when being moved from the transport driver bay 1416 to the introduction chamber 1401. In order to avoid this physical interference, after the gripper arm 1408 grasps the wire holder 1410, the gripper arm 1408 is moved in the direction (inner side) in which the wire is slack so as not to interfere with another gripper arm 1408. Furthermore, this set up is preferable because, if the gripper arm 1408 is moved backward only by as much as it has been moved in the opposite direction after the gripper arm 1408 is moved back to the introduction chamber 1401, there is no interference between one of the gripper arms 1408 and a different one of the gripper arms 1408 and the wire holders 1410 can be transported in order.

In the same way, when the gripper arm 1408 is moved from the discharge chamber 1405 to the transport driver bay 1416, this set up is preferable because, when the gripper arm 1408 is moved along the outer side after being separated from the wire holder 1410 and returned to the discharge chamber 1405, there is no physical interference and the wire holders 1410 can be transported from the support arm 1414 in order.

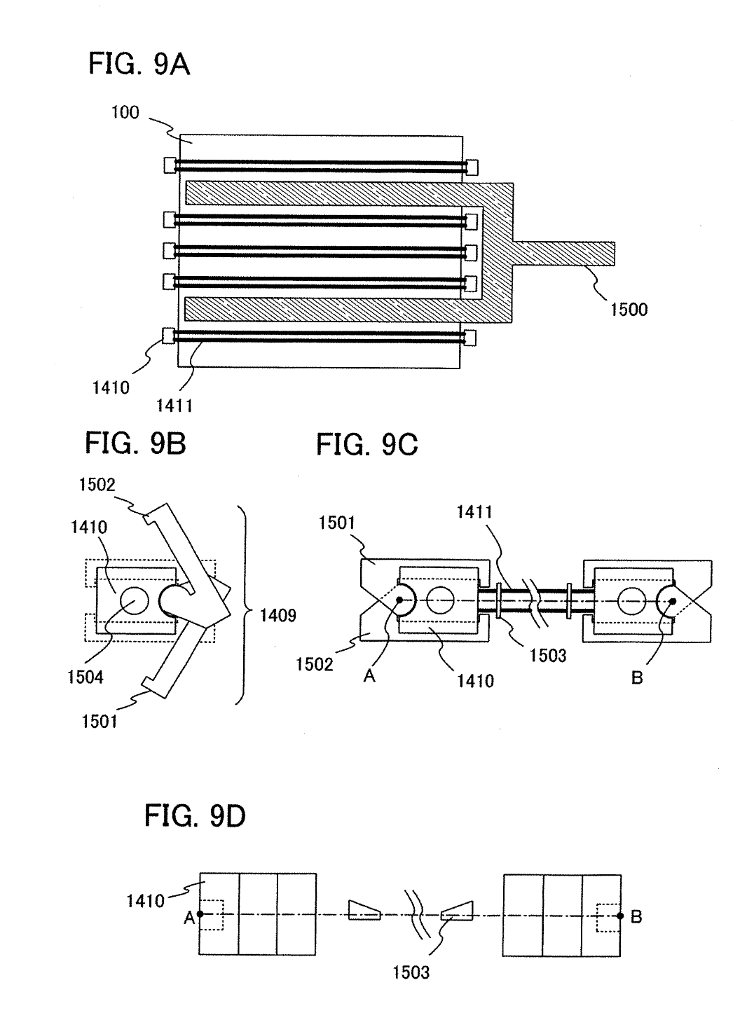

Here, a structure used to support the substrate 100 in the introduction chamber will be described using FIGS. 9A to 9D. In FIG. 9A, a diagram of a state in which the substrate 100 that is transported to the transport chamber of the impurity introduction unit is mounted onto a plurality of the wires 1411 as seen from a back surface direction is illustrated. Here, the edge of each side of the wires 1411 are held in place by a pair of the wire holders 1410. Furthermore, each pair of the wire holders 1410 can hold at least one of the wires 1411 in place.

In this way, the substrate 100 is directly supported by the wire 1411, but the substrate 100 cannot be supported in the introduction chamber unless the wire holder 1410 is supported. Consequently, a support mechanism used to support the wire holder 1410 in the introduction chamber will be described using enlarged top-view diagrams shown in FIGS. 9B and 9C. It is to be noted that FIG. 9B is an enlarged top-view diagram of the wire holder 1410 and the support mechanism 1409 and FIG. 9C is an enlarged top-view diagram of a pair of the wire holders 1410 and a pair of support mechanisms that support the pair of the wire holders 1410.

As shown in FIG. 9B, each of the support mechanisms 1409 has a first gripper 1501 and a second gripper 1502 and can grasp onto or release the wire holder 1410. Specifically, the first gripper 1501 and the second gripper 1502 can open and close in a direction that pinches the wire holder 1410. Hereby, as shown in FIG. 9C, there is no physical interference between the wires 1410, and each of the wire holders 1410 can be grasped or released by the first gripper 1501 and the second gripper 1502. As described above, in the introduction chamber, the wire holder 1410 is supported by the support mechanism 1409; however, in transportation of the substrate from the introduction chamber to the impurity atmosphere chamber, the wire holder 1410 is grasped by the gripper arm and released from the support mechanism 1409.

Furthermore, as shown in FIG. 9C, each of the wires 1411 may have at least two of a part 1503 that touches the edge of the substrate when the substrate is placed on the wires 1411. By provision of the part 1503 that touches the edge of the substrate, the substrate can be prevented from slipping out. FIG. 9D is a cross-sectional-view diagram of a cross section taken along a dotted line A-B in FIG. 9C. As shown in FIG. 9D, in consideration of the operating range for when the substrate is transferred by a transfer robot, the surface of the part 1503, which touches the edge of the substrate, that comes into contact with the substrate may be slanted.

It is to be noted that the support mechanism 1412 in the impurity introduction chamber 1404 shown in FIG. 8 and the support mechanism 1417 in the transport driver bay 1416 shown in FIG. 7 both have the same structure as the support mechanism 1409 shown in FIGS. 9B and 9C, there is no physical interference between the wires 1410, and each of the wire holders 1410 can be grasped or released by the support mechanism. In the impurity atmosphere chamber, the wire holder 1410 is supported by the support mechanism 1412, but in transport of the substrate from the impurity introduction chamber to the discharge chamber, the wire holder 1410 is supported by the support arm and released from the support mechanism 1412. It is to be noted that the wire holder 1410 may have a hole 1504, as shown in FIG. 9B. By insertion of the support arm into the hole 1504, the wire holder 1410 can be supported by the support arm.

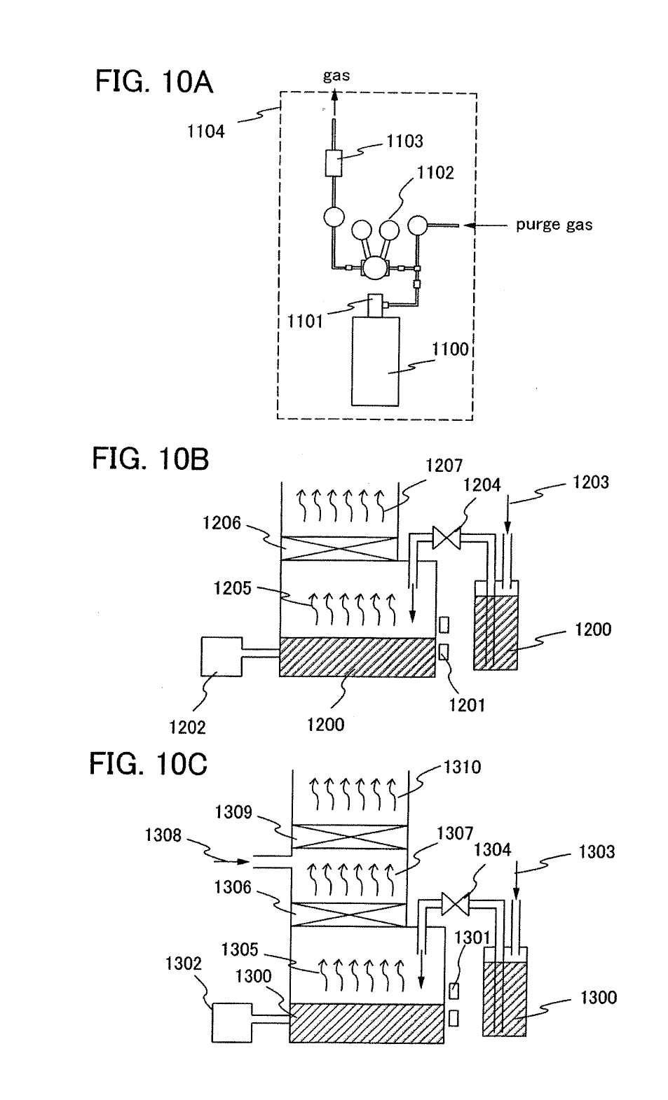

Next, a structure of the impurity generator 1415 will be described using FIG. 10A. The impurity generator has a gas canister 1100 that contains an impurity, an emergency cutoff valve 1101, a regulator 1102, and a mass flow controller 1103. The pressure inside a cabinet 1104 in which the impurity generator 1415 is placed is set to be a negative pressure with respect to external pressure so that the impurity is not leaked to external. An impurity gas discharged from the gas canister 1100 is supplied to the impurity atmosphere chamber 1404 through the mass flow controller 1103 after the pressure of the gas is adjusted by the regulator 1102.

It is to be noted that, for the impurity gas, a gas, such as diborane (B₂H₆), phosphine (PH₃), or the like, that contains an element belonging to group 13 or group 15 of the periodic table may be diluted and used. In addition, for a dilution gas, hydrogen, argon, helium, neon, or the like can be used. However, because diffusion of impurities occurs if the amount of the element of the dilution gas absorbed into the semiconductor film increases, resulting in deterioration of electrical characteristics, preferably, hydrogen is used as the dilution gas. Furthermore, in the case where the impurity gas has a high level of toxicity, the structure may be one in which exhaust vents provided in the introduction chamber, the impurity atmosphere chamber, and the discharge chamber are each connected to an abatement system.

It is to be noted that the structure of the impurity introduction chamber in the semiconductor manufacturing apparatus of the present invention is not limited to that of the present embodiment mode. For example, a supply and exhaust vent used for adjustment of the impurity concentration may be provided in the impurity introduction unit. By provision of the supply and exhaust vent, simplification of maintenance and optimization of process conditions can be achieved. In addition, retention of a substrate in the impurity introduction unit is not limited to being done using a wire; for example, a cassette in which a plurality of substrates can be loaded may be also used. In this case, by a cassette being set in a stocker of the impurity introduction unit, a plurality of substrates can be retained in the impurity atmosphere. For the cassette, an object commonly used in the semiconductor industry that is formed of a macromolecular material by injection molding or the like can be used. For the macromolecular material, a fluoroplastic PFA, a fluoroplastic PVDF, a fluoroplastic ECTFE, a fluoroplastic ETFE, polycarbonate, polypropylene, polyethylene, and the like can be given.

Furthermore, in the present embodiment mode, an example is given in which an impurity gas is generated using the gas canister 1100 that contains an impurity in the impurity generator 1415; however, the embodiment of the present invention is not limited to being the embodiment given as the example here. For example, the impurity gas may be generated using a chemical solution or a fan filter unit, as well. A case in which a chemical solution and a fan filter unit (hereinafter referred to as an FFU) shown in FIG. 10B are used for the impurity generator 1415 will be described.

The impurity generator shown in FIG. 10B has a chemical solution 1200, a compressed gas introducer 1203 used to push out the chemical solution, a valve 1204, a fluid level sensor 1201, a chemical solution temperature adjustment mechanism 1202, and an FFU 1206. The chemical solution 1200 is heated and vaporized by the chemical solution temperature adjustment mechanism 1202 and turned into a vapor 1205 of the chemical solution. It is to be noted that the fluid level sensor 1201 is provided with the objective of detecting the fluid volume of the chemical solution 1200 for safety reasons. For the chemical solution 1200, a solution that contains an impurity may be used, or a solution that does not contain an impurity may be used. When an acid or an alkali solution that does not contain an impurity is used for the chemical solution 1200, for example, a filter that contains an impurity is used for the filter of the FFU 1206, the impurity in the filter is eluted by the vapor 1205 of the chemical solution, and a vapor 1207 that contains the impurity is sent out to the impurity atmosphere chamber by a fan.

In addition, when a solution that contains an impurity is used for the chemical solution 1200, the filter of the FFU 1206 may or may not contain an impurity. For a chemical solution that contains an impurity, an inorganic acid that contains boron such as boric acid or the like, for example, a borate such as trimethyl borate, triethyl borate, triisopropyl borate, tripropyl borate, tri-n-octyl borate, an aqueous solution of ammonium borate, or the like; a phosphate, for example, trimethyl phosphate, triethyl phosphate, tri-n-amyl phosphate, 2-ethylhexyl diphenyl phosphate, an aqueous solution of ammonium phosphate, or the like; or the like may be used.

It is to be noted that the filter of the FFU also has an objective of removing particles, and a combination of a chemical filter, a HEPA filter, and a ULPA filter may be used, depending on the objective.

Moreover, the impurity generator 1415 may have a structure in which a plurality of FFUs is provided, as shown in FIG. 10C. The impurity generator shown in FIG. 10C has a chemical solution 1300, a compressed gas introducer 1303 used to push out the chemical solution, a valve 1304, a fluid level sensor 1301, a chemical solution temperature adjustment mechanism 1302, a first FFU 1306, a humidity control mechanism 1308, and a second FFU 1309.

For the chemical solution, an ester compound that contains an impurity is used, an ester compound 1305 that is volatilized by the chemical solution temperature adjustment mechanism 1302 is extracted by the first FFU 1306, the amount of humidity is adjusted by moisture by the humidity control mechanism 1308 and the ester compound 1305 is hydrolyzed, and a mixed vapor 1307 that is decomposed into alcohol and an acid that contains an impurity is formed. Then, the alcohol constituent is removed by a filter in the second FFU 1309, and a vapor 1310 that contains the acid, which contains an impurity, as its main component is formed. It is to be noted that, for the ester compound that contains an impurity, for example, trimethyl borate, triethyl borate, triisopropyl borate, tripropyl borate, tri-n-octyl borate, trimethyl phosphate, triethyl phosphate, tri-n-amyl phosphate, 2-ethyhexyl diphenyl phosphate, or the like may be used.

It is to be noted that the filter of the first FFU 1306 or that of the second FFU 1309 also has an objective of removing particles, and any of a chemical filter, a HEPA filter, and a ULPA filter may be combined together, depending on the objective, and used, or a fan only may be used.

In the structure of the impurity introduction unit given in the present embodiment mode, by use of a wire as a substrate support, flexure of a substrate holding mechanism caused by the weight of the substrate itself can be suppressed. As a result, the amount of space between substrates within the unit can be decreased, and the weight of parts used in the substrate support can be reduced. Furthermore, because each structural component of the unit is made up of a simple structure, the number of different types of parts used can be reduced by the number of parts that can be used in common being increased, maintenance can be improved, and equipment costs can be dramatically reduced.

By use of the semiconductor manufacturing apparatus that is equipped with the impurity introduction unity that is presented in the present embodiment mode, an impurity can be introduced into a semiconductor film at low concentration and at a high level of accuracy. As a result, variations in threshold voltage of semiconductor devices formed by use of these semiconductor films can be suppressed, and high performance semiconductor devices can be fabricated at high productivity and high yield. Furthermore, because no expensive doping apparatus is used in the introduction of the impurity into the semiconductor film, it becomes possible to provide semiconductor devices at low cost.

In addition, by use of the semiconductor manufacturing apparatus that is equipped with the impurity introduction unit that is presented in the present embodiment mode, because an impurity can be attached to a plurality of substrates over which a semiconductor film has been formed all at the same time and the amount of the impurity attached to the semiconductor film of each substrate can be controlled efficiently, productivity can be increased dramatically.

### Embodiment Mode 3

In the present embodiment mode, steps by which a thin film transistor (a TFT) is fabricated by use of the semiconductor manufacturing apparatus of the present invention and by use of a crystalline semiconductor film, which contains an impurity at low concentration, fabricated according to the fabrication steps given in Embodiment Mode 1 will be described. It is to be noted that a fabrication method of a top gate (forward staggered) TFT is described in the present embodiment mode; however, the present invention can be used for a bottom gate (reverse staggered) TFT or the like in the same way. However, the present invention can be implemented in a lot of different modes, and it is to be easily understood by those skilled in the art that various changes and modifications can be made without any departure from the spirit and scope of the present invention. Accordingly, the present invention is not to be taken as being limited to the described content of the embodiment mode included herein.

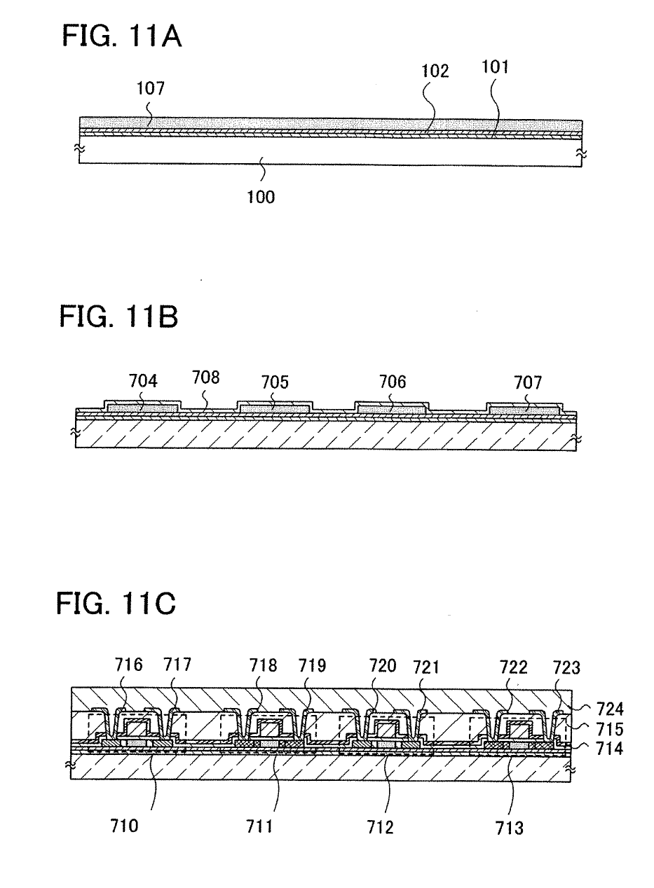

First, as shown in FIG. 11A, the silicon nitride film 101 that is used as a base insulating film, the silicon oxide film 102, and the crystalline semiconductor film 107, which contains an impurity at low concentration, that is formed using the semiconductor manufacturing apparatus of the present invention are formed and stacked over the substrate 100 in the order given. It is to be noted that, in the present embodiment mode, the impurity is contained in the crystalline semiconductor film 107 that contains an impurity at low concentration at a concentration of from 1×10¹⁵ atoms/cm³ to 1×10¹⁸ atoms/cm³. In addition, steps up to through the step for formation of the crystalline semiconductor film 107 can be performed in the same way as the steps shown in FIGS. 2A to 2E or in FIGS. 4A to 4D.

Next, as shown in FIG. 11B, the crystalline semiconductor film 107 that contains an impurity at low concentration is etched, and island-shaped semiconductor films 704 to 707 are formed. Then, a gate insulating film 708 is formed so as to cover the island-shaped semiconductor films 704 to 707. In the formation of the gate insulating film 708, for example, silicon oxide, silicon nitride, silicon nitride oxide, or the like can be used. For the film formation method used in the formation of the gate insulating film 708, a plasma CVD method, a sputtering method, or the like can be used. For example, an insulating film that contains silicon at a film thickness of from 30 nm to 200 nm may be formed by use of a sputtering method.

Next, gate electrodes are formed by etching of conductive layers formed over the gate insulating film 708. Then, using the gate electrodes or a resist that is formed and etched as a mask, impurities imparting n-type or p-type conductivity are added to the island-shaped semiconductor films 704 to 707 as selected, and source regions, drain regions, LDD regions, and the like are formed. By the steps described above, n-type transistors 710 and 712 and p-type transistors 711 and 713 can be formed over the same substrate (FIG. 11C). Subsequently, an insulating film 714 that is used as a protective film of these transistors is formed. For this insulating film 714, an insulating film that contains silicon with a film thickness of from 100 nm to 200 nm may be formed as a single-layer or stacked-layer structure using a plasma CVD method or a sputtering method. For example, a silicon oxynitride film with a film thickness of 100 nm may be formed by a plasma CVD method.

Subsequently, an organic insulating film 715 is formed over the insulating film 714. For the organic insulating film 715, an organic insulating film of polyimide, polyamide, BCB, acrylic, or the like that is applied by an SOG method is used. Because the organic insulating film 715 reduces the amount of unevenness due to a TFT formed over the substrate 100, with a strong implication being that the organic insulating film 715 is used to planarize the substrate 100, it is preferable that a film that has an excellent level of flatness be used for the organic insulating film 715. Moreover, using a photolithography method, the insulating film 714 and the organic insulating film 715 are processed into patterns, and contact holes that reach the impurity regions are formed therein.

Next, a conductive film is formed using a conductive material and processed into a pattern, whereby wirings 716 to 723 are formed. Then, with formation of an insulating film 724 that is used as a protective film, a semiconductor device like that illustrated in FIG. 11C is completed.

It is to be noted that a fabrication method of a semiconductor device manufactured using the semiconductor manufacturing apparatus of the present invention is not limited to having the steps described above for fabrication of a TFT. In the present invention, a crystalline semiconductor film, which contains an impurity at low concentration and is obtained by exposure of a semiconductor film to an impurity atmosphere and irradiation thereafter of the semiconductor film with a laser beam, is used as an active layer of a TFT. As a result thereof, the amount of variation in the threshold voltage of semiconductor elements formed using the semiconductor films can be suppressed.

Furthermore, in the semiconductor manufacturing apparatus of the present invention, a crystallization step that uses a catalytic element may be performed before crystallization by laser beam is performed. For the catalytic element, an element such as nickel (Ni), germanium (Ge), iron (Fe), palladium (Pd), tin (Sn), lead (Pb), cobalt (Co), platinum (Pt), copper (Cu), or gold (Au) can be used. If a crystallization step of crystallization by laser beam is performed after the crystallization step that uses a catalytic element is performed, crystals formed when crystallization is performed by use of the catalytic element are left remaining without being melted by irradiation with a laser beam, and crystallization proceeds with these crystals used as crystal nuclei.

For this reason, compared to a case in which only a step for crystallization by laser beam is performed, crystallinity of the semiconductor film can be improved even more, and the amount of roughness on the surface of the semiconductor film after crystallization by laser beam has been performed can be suppressed. Consequently, the amount of variation in the characteristics of semiconductor elements (for example, TFTs) that are to be formed later can be suppressed even more. It is to be noted that crystallinity by irradiation with a laser beam may be increased even more with promotion of crystallization by performance of heat treatment after the addition of a catalytic element, or the heat treatment step may be omitted. Specifically, crystallinity may be set to be increased by irradiation with a laser beam instead of by heat treatment, after the catalytic element has been added.

In the present invention, an example is given in which the semiconductor manufacturing apparatus of the present invention is used in the introduction of an impurity into a channel formation region, but the semiconductor manufacturing apparatus of the present invention may be used in the introduction of an impurity into an LDD region or into a source region or a drain region, as well. In addition, a fabrication method of a semiconductor device formed by use of the present invention can be used for the fabrication method of an integrated circuit or a semiconductor display device, as well. For transistors applied to functional circuits of drivers, CPUs, and the like, an LDD structure or a structure in which an LDD is overlapped with a gate electrode would be the preferred structure, and for an increase in speed, it is preferable that miniaturization of the transistor be achieved. Because the transistors 710 to 713 completed by use of the present embodiment mode have LDD structures, use in a driver circuit that requires a low I_{off} is preferable.

By use of the semiconductor manufacturing apparatus of the present invention, an impurity can be introduced into a semiconductor film at low concentration and at a high level of accuracy. As a result, variations in threshold voltage of semiconductor devices formed by use of these semiconductor films can be suppressed, and high performance semiconductor devices can be fabricated at high productivity and high yield. Furthermore, because no expensive doping apparatus is used in the introduction of the impurity into the semiconductor film, it becomes possible to provide semiconductor devices at low cost.

### Embodiment Mode 4

In the present embodiment mode, a process by which a thin film integrated circuit or a contactless thin film integrated circuit device (also referred to as a wireless chip, a wireless IC tag, and radio frequency identification (RFID, wireless identification) is fabricated using the semiconductor manufacturing apparatus of the present invention is given. However, the present invention can be implemented in a lot of different modes, and it is to be easily understood by those skilled in the art that various changes and modifications can be made without any departure from the spirit and scope of the present invention. Accordingly, the present invention is not to be taken as being limited to the described content of the embodiment mode included herein.

An example in which an electrically isolated TFT is used for a semiconductor element that is used in an integrated circuit of a wireless IC tag will be shown hereinafter; however, a semiconductor element that is used in an integrated circuit of a wireless IC tag is not limited to being a TFT, and any kind of element can be used. For example, in addition to a TFT, a memory element, a diode, a photoelectric element, a resistive element, a coil, a capacitive element, an inductor, and the like can typically be given.

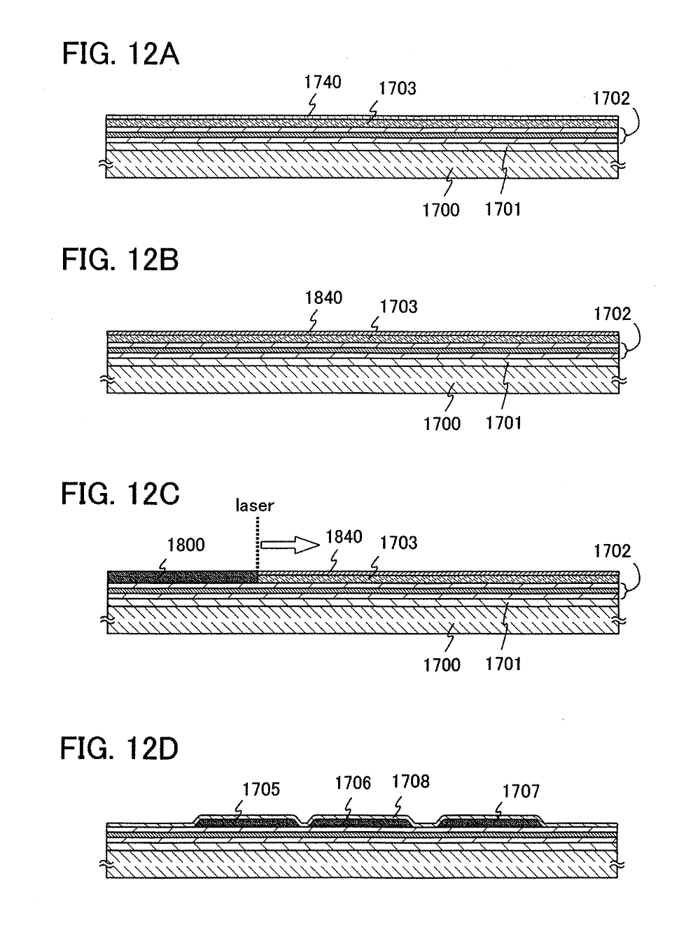

At first, steps for fabrication of a thin film integrated circuit will be described using FIGS. 12A to 12D, FIGS. 13A to 13C, FIGS. 14A to 14C, FIGS. 15A and 15B, FIGS. 16A to 16C, and FIGS. 17A and 17B. First, a separation layer 1701 is formed over a substrate (a first substrate) 1700 (FIG. 12A). The separation layer 1701 can be formed using a sputtering method, a low-pressure CVD method, a plasma CVD method, or the like. In the present embodiment mode, a film of amorphous silicon with a thickness of approximately 50 nm is formed by a sputtering method and used for the separation layer 1701. It is to be noted that the separation layer 1701 is not limited to being silicon but may be formed of a material (for example, tungsten, molybdenum, or the like) that can be removed as selected by etching. It is desirable that the film thickness of the separation layer 1701 be set to be from 50 nm to 60 nm.

Next, a base insulating film 1702 is formed over the separation layer 1701. The base insulating film 1702 is provided for the prevention of diffusion of an alkali metal such as Na or the like or an alkali earth metal that is contained in the first substrate into the semiconductor film and the prevention of adverse effects on the characteristics of a semiconductor element such as a TFT or the like. Furthermore, the base insulating film 1702 also has the function of protection of the semiconductor element during a step to be performed later in which the semiconductor element is separated from the substrate. The base insulating film 1702 may be a single layer or a film in which a plurality of insulating films are stacked together. Consequently, the base insulating film 1702 is formed using an insulating film of silicon oxide, silicon nitride, silicon oxide that contains nitrogen (SiON), silicon nitride that contains oxygen (SiNO), or the like that can suppress the diffusion of an alkali metal or an alkali earth metal into the semiconductor film.

Next, a semiconductor film 1703 is formed over the base insulating film 1702. It is preferable that the semiconductor film 1703 is formed after the base insulating film 1703 is formed without being exposed to the atmosphere. The film thickness of the semiconductor film 1703 is set to be from 20 nm to 200 nm, (desirably, from 40 nm to 170 nm, even more desirably, from 50 nm to 150 nm). In the present embodiment mode, an amorphous silicon film is formed as the semiconductor film 1703.

It is to be noted that, after an amorphous silicon film is formed for the semiconductor film 1703, the amorphous silicon film may be heated at 500° C. in an electric furnace for one hour in order to release hydrogen from the amorphous silicon film. Removing hydrogen is performed in order to prevent bumping of hydrogen gas in the semiconductor film 1703 at the time that the semiconductor film 1703 is irradiated with a laser beam and to prevent ablation of the semiconductor film 1703 but can be omitted if the amount of hydrogen contained in the semiconductor film 1703 is low.

Next, the substrate 1700 over which the semiconductor film 1703 is formed by the steps described above is transported to the prewashing unit that is used to eliminate impurities of the semiconductor manufacturing device of the present invention. Because an oxidized film layer 1740 is formed over the semiconductor film 1703 by heat treatment or the like that is performed when the film is formed or when hydrogen is removed from the film, impurities such as the oxidized film layer or the like that are not needed for doping are removed by a sheet-fed spin washing machine in the unit, and the semiconductor film 1703 is spun dry after being exposed.

The substrate 1700 from which impurities not needed for doping are removed is transported to the impurity introduction chamber and exposed to the impurity atmosphere for only the length of time required for attachment of an impurity at a desired concentration. Hereby, as shown in FIG. 12B, an impurity 1840 can be attached to the semiconductor film 1703 at the desired concentration.

Next, in the laser crystallization unit, as shown in FIG. 12C, by irradiation of the semiconductor film 1703 with a laser beam, simultaneous with melting of the semiconductor film 1703, the impurity 1840 is diffused throughout the melted semiconductor film 1703. After irradiation with a laser beam is completed, heat is diffused from the melted semiconductor film 1703, the semiconductor film 1703 is crystallized by cooling, and a crystalline semiconductor film 1800 that contains an impurity at low concentration is formed. It is to be noted that, in the part of the crystalline semiconductor film that corresponds to a channel formation region of a TFT, an impurity is introduced at a concentration of from 1×10¹⁵ atoms/cm³ to 1×10¹⁸ atoms/cm³.

Next, as shown in FIG. 12D, after the crystalline semiconductor film 1800 is etched and island-shaped semiconductor films 1705 to 1707 are formed, a gate insulating film 1708 is formed. The gate insulating film 1708 can be formed of a single layer or of stacked layers of silicon nitride, silicon oxide, silicon oxide that contains nitrogen, or silicon nitride that contains oxygen using a plasma CVD method, a sputtering method, or the like.

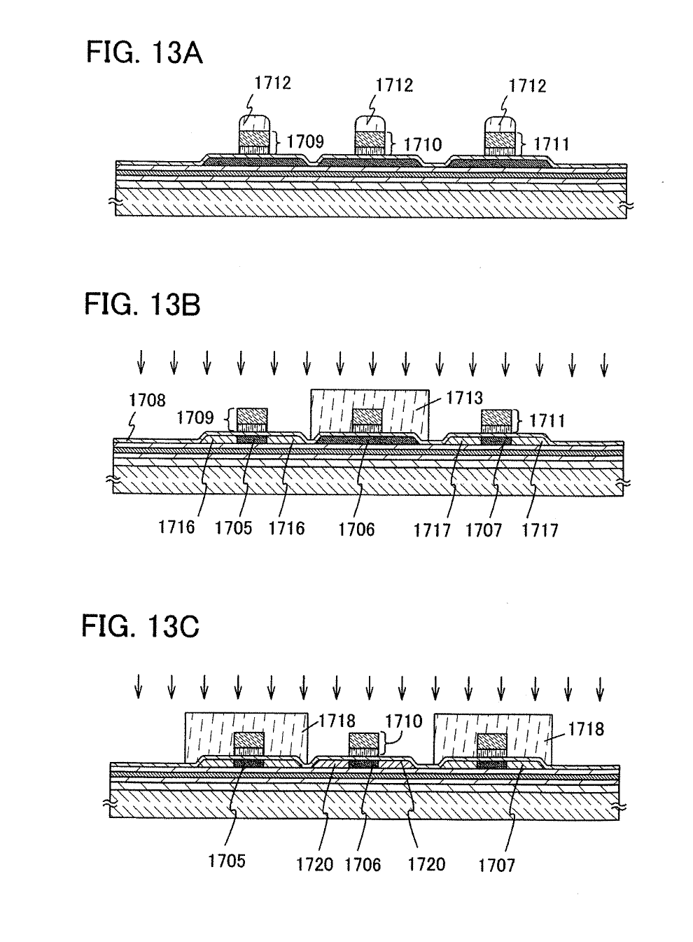

Next, as shown in FIG. 13A, gate electrodes 1709 to 1711 are formed. Here, after Si and W are formed by a sputtering method so as to be stacked together, etching is performed using resists 1712 as masks, and the gate electrodes 1709 to 1711 are formed. Of course, the conductive materials, structure, and formation methods for the gate electrodes 1709 to 1711 are not to be taken as being limited to these but can be selected as appropriate. For example, a stacked-layer structure of silicon that has been doped with an impurity (phosphorus, arsenic, or the like) that imparts n-type conductivity and a nickel silicide or a stacked-layer structure of tantalum nitride and tungsten may be used, as well. In addition, the gate electrodes may also each be formed as a single layer using different kinds of conductive materials. Moreover, in the case in which a gate electrode and an antenna are formed at the same time, materials may be selected in consideration of the functions of the gate electrode and the antenna.

Instead of a resist mask, a mask of silicon oxide or the like may be used, as well. In this case, although a step in which a mask (referred to as a hard mask) of silicon oxide, silicon oxide that contains nitrogen, or the like is formed is added, because the amount of reduction in film thickness during etching is less for a mask than for a resist, the gate electrodes 1709 to 1711 can each be formed with a desired width. Furthermore, the gate electrodes 1709 to 1711 may also be formed as selected using a liquid droplet discharge method without any use of the masks 1712.

Next, as shown in FIG. 13B, the island-shaped semiconductor film 1706, which is to be a p-type TFT, is covered by a resist 1713, and the island-shaped semiconductor films 1705 and 1707 are doped with an impurity (typically, phosphorus (P) or arsenic (As)) that imparts n-type conductivity using the gate electrodes 1709 and 1711 as masks. By this doping step, the island-shaped semiconductor films 1705 and 1707 are doped through the gate insulating film 1708, and a pair of low-concentration impurity regions 1716 and 1717 are formed, each formed in one of the island-shaped semiconductor films 1705 and 1707. It is to be noted that this doping step may also be performed with the island-shaped semiconductor film 1706, which is to be a p-type TFT, not being covered by the resist 1713.

Next, as shown in FIG. 13C, after the resist 1713 is removed by ashing or the like, a resist 1718 is formed anew so as to cover the island-shaped semiconductor films 1705 and 1707, which are to be n-type TFTs, and the island-shaped semiconductor film 1706 is doped with an impurity (typically, boron (B)) that imparts p-type conductivity using the gate electrode 1710 as a mask. By this doping step, the island-shaped semiconductor film 1706 is doped through the gate insulating film 1708, and a pair of high-concentration p-type impurity regions 1720 are formed in the island-shaped semiconductor film 1706.

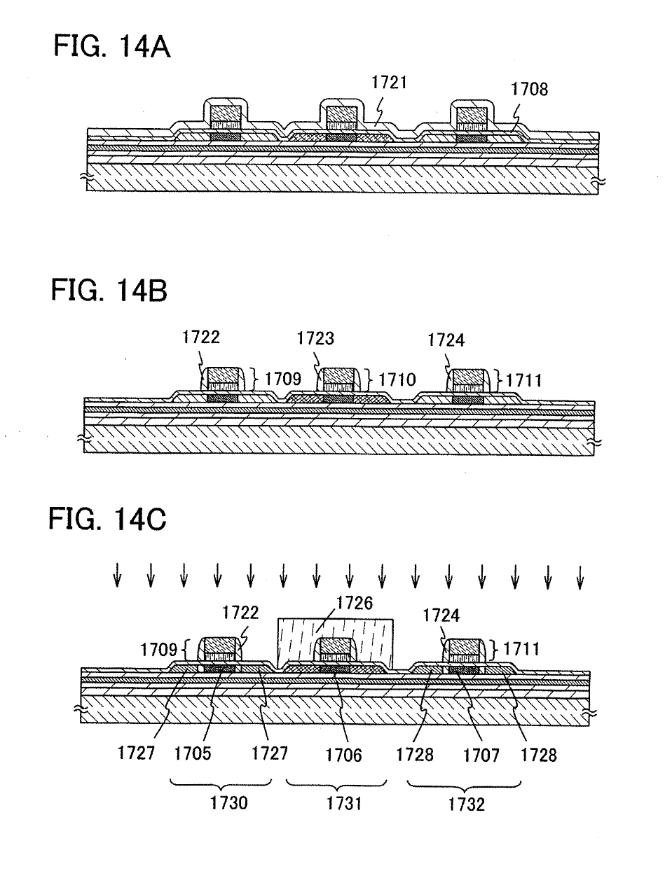

Next, as shown in FIG. 14A, after the resist 1718 is removed by ashing or the like, an insulating film 1721 is formed so as to cover the gate insulating film 1708 and the gate electrodes 1709 to 1711.

Subsequently, by an etch-back method, parts of the insulating film 1721 and the gate insulating film 1708 are etched, and as shown in FIG. 14B, sidewalls 1722 to 1724 that come into contact with sidewalls of the gate electrodes 1709 to 1712 are formed in a self-aligning manner. For an etching gas, a mixed gas of CHF₃ and He, for example, can be used. It is to be noted that the steps for formation of the sidewalls are not limited to being the steps given here.

Next, as shown in FIG. 14C, a resist 1726 is formed anew so as to cover the island-shaped semiconductor film 1706, which is to be a p-type TFT, and the island-shaped semiconductor films 1705 and 1707 are doped with an impurity (for example, P or As) that imparts n-type conductivity at high concentration using the gate electrodes 1709 and 1711 and the sidewalls 1722 and 1724 as masks. By this doping step, the island-shaped semiconductor films 1705 and 1707 are doped through the gate insulating film 1708, and a pair of high-concentration n-type impurity regions 1727 and 1728 are formed in the island-shaped semiconductor films 1705 and 1707.

Next, after the resist 1726 is removed by ashing or the like, thermal activation of the impurity regions may be performed. For example, after a silicon oxide film that contains nitrogen is formed at a film thickness of 50 nm, heat treatment may be performed in a nitrogen atmosphere at a temperature of 550° C. for four hours. Furthermore, the number of defects in a polycrystalline semiconductor film can be decreased by performance of heat treatment in a nitrogen atmosphere at a temperature of 410° C. for one hour after a silicon nitride film that contains hydrogen is formed at a film thickness of 100 nm. This process is used, for example, to terminate dangling bonds present in the polycrystalline semiconductor film and is referred to as a hydrogen treatment process or the like.

By the sequence of steps described above, an n-channel TFT 1730, a p-channel TFT 1731, and an n-channel TFT 1732 are formed. In the fabrication steps given above, by the conditions for the etching method being changed as appropriate and the size of the sidewalls being adjusted, a TFT with an LDD length of from 0.2 μm to 2 μm can be formed. Furthermore, a passivation film that is used to protect the TFTs 1730 to 1732 may be formed thereafter.

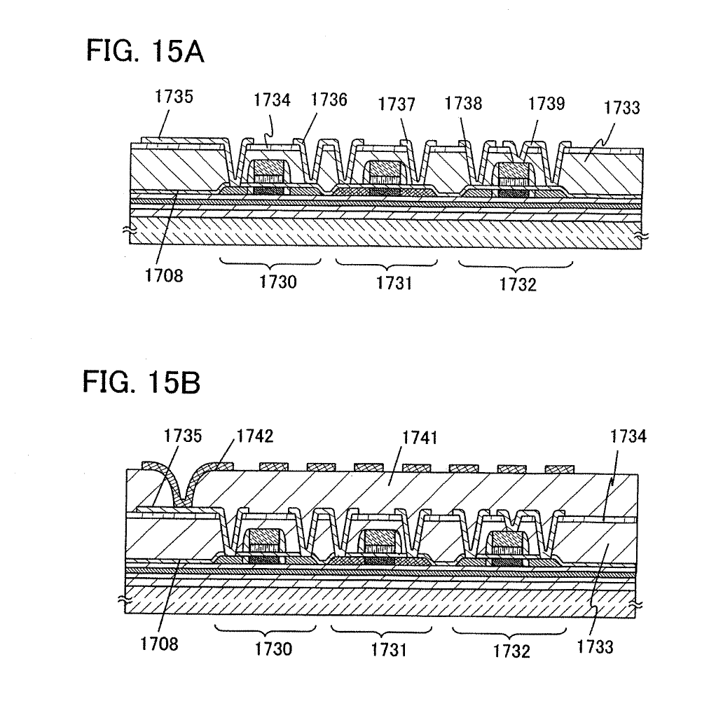

Next, as shown in FIG. 15A, a first interlayer insulating film 1733 is formed so as to cover the TFTs 1730 to 1732. In addition, a second interlayer insulating film 1734 is formed over the first interlayer insulating film 1733. It is to be noted that, in order to prevent film peeling or cracking of the first interlayer insulating film 1733 or second interlayer insulating film 1734 caused by stress due to a difference in the coefficients of thermal expansion between that of the first interlayer insulating film 1733 or second interlayer insulating film 1734 and that of conductive materials and the like that make up wirings that are to be formed later, a filler may be mixed into the first interlayer insulating film 1733 or second interlayer insulating film 1734.

Next, contact holes are formed in the first interlayer insulating film 1733, the second interlayer insulating film 1734, and the gate insulating film 1708, and wirings 1735 to 1739 that are to be connected to the TFTs 1730 to 1732 are formed. It is to be noted that the wirings 1735 and 1736 are connected to the high-concentration impurity region 1727 of the n-channel TFT 1730, the wirings 1736 and 1737 are connected to the high-concentration impurity region 1720 of the p-channel TFT 1731, and the wirings 1738 and 1739 are connected to the high-concentration impurity region 1728 of the n-channel TFT 1732. Furthermore, the wiring 1739 is also connected to the gate electrode 1711 of the n-channel TFT 1732. The n-channel TFT 1732 can be used as a random number ROM memory element.

Next, as shown in FIG. 15B, a third interlayer insulating film 1741 is formed over the second interlayer insulating film 1734 so as to cover the wirings 1735 to 1739. The third interlayer insulating film 1741 is formed so as to have an opening in a location in which part of the wiring 1735 would be exposed. It is to be noted that the third interlayer insulating film 1741 can be formed using the same materials as those used to form the first interlayer insulating film 1733.

Next, an antenna 1742 is formed over the third interlayer insulating film 1741. For the antenna 1742, a conductive material that contains one or more of a metal, such as Ag, Au, Cu, Pd, Cr, Mo, Ti, Ta, W, Al, Fe, Co, Zn, Sn, Ni, or the like, or a metal compound containing one or more of the metals given can be used. The antenna 1742 is also connected to the wiring 1735. It is to be noted that the antenna 1742 is connected to the wiring 1735 directly in FIG. 15B, but the wireless IC tag of the present invention is not limited to having this kind of structure. For example, the structure can be set to be one in which the antenna 1742 is electrically connected to the wiring 1735 using a wiring that is formed separately.

The antenna 1742 can be formed using a printing method, a photolithography method, an evaporation method, a liquid droplet discharge method, or the like. In FIG. 15B, the antenna 1742 is formed of a conductive film of a single layer, but the antenna 1742 can also be formed of a plurality of conductive films that are stacked together. For example, the antenna 1742 may be formed by coating of copper over a wiring formed of Ni or the like by electroless plating. It is to be noted that “liquid droplet discharge method” refers to a method in which liquid droplets that contain a given composition are discharged through pores and formed into a given pattern, and inkjet methods and the like are included in this category. Furthermore, screen printing methods, offset printing methods, and the like are also included in the category of printing methods. By use of a printing method or a liquid droplet discharge method, the antenna 1742 can be formed without any need for a mask used for lithographic exposure. Furthermore, liquid droplet discharge methods and printing methods differ from photolithography methods in that there is no waste of material, such as removal of material by etching, with those methods unlike with photolithography methods. In addition, because expensive masks used for lithographic exposure need not be used, costs incurred in the fabrication of wireless IC tags can be suppressed.

When a liquid droplet discharge method or a printing method is used, conductive particles of Cu coated with Ag and the like can also be used. It is to be noted that when the antenna 1742 is formed using a liquid droplet discharge method, having the surface of the third interlayer insulating layer 1741 be treated in such a way that the adhesiveness of the antenna 1742 is increased is desirable. For a method by which the adhesiveness can be increased, specifically, for example, a method in which a metal or a metal compound by which the adhesiveness of a conductive film or an insulating film can be increased by catalytic action is attached to the surface of the third interlayer insulating film 1741; a method in which an organic insulating film, a metal, or a metal compound that has a high level of adhesiveness in regard to a conductive film or insulating film that is formed is attached to the surface of the third interlayer insulating film 1741; a method in which surface modification is performed by the surface of the third interlayer insulating film 1741 being treated by plasma treatment under atmospheric pressure or reduced pressure; and the like can be given.

If the metal or metal compound that is attached to the third layer interlayer insulating film 1741 is conductive, the sheet resistance of the metal or metal compound is controlled so that there is no disruption in the normal operation of the antenna 1742. Specifically, either the average thickness of the metal or metal compound that is conductive may be controlled so as to be from, for example, 1 nm to 10 nm, or a part of or all of the metal or metal compound may be made to be insulative by oxidation. Alternatively, regions other than those in which it is desired that adhesiveness be increased may be removed as selected by etching of the adhered metal or metal compound. Moreover, instead of the metal or metal compound being attached to the entire surface of the substrate in advance, the metal or metal compound may be attached to the substrate as selected in specified regions only using a liquid droplet discharge method, a printing method, a sol gel method, or the like. It is to be noted that there is no need for the metal or metal compound to be formed over the surface of the third interlayer insulating film 1741 in a perfectly continuous film shape, and the metal or metal compound may be formed in a dispersed manner to some extent.

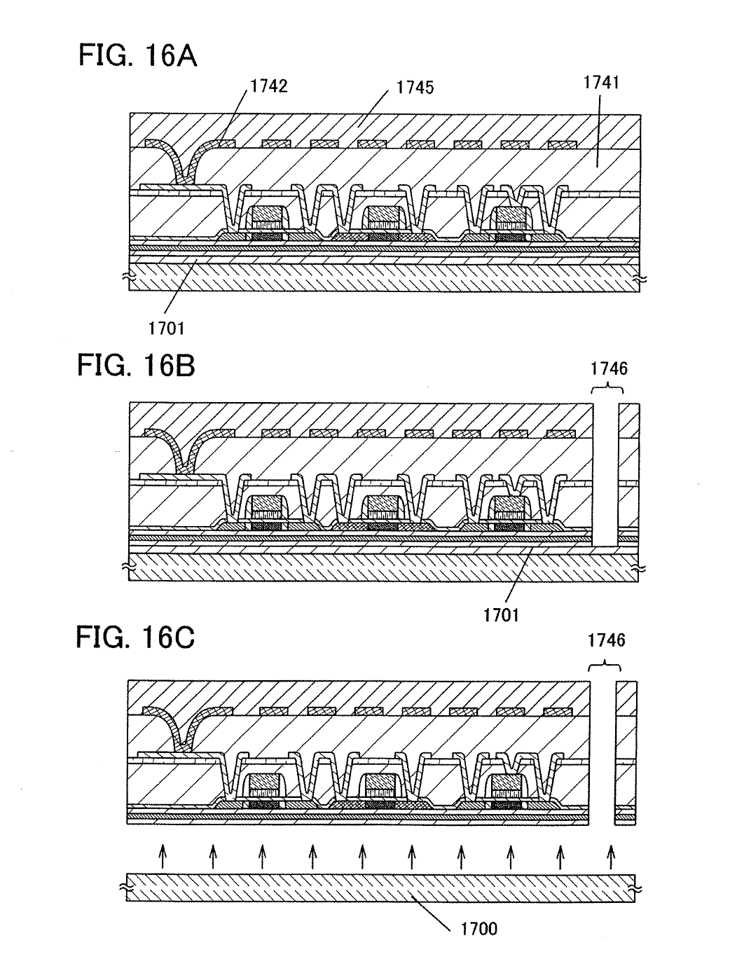

After the antenna 1742 is formed, a protective layer 1745 is formed over the third interlayer insulating film 1741 so as to cover the antenna 1742, as shown in FIG. 16A. For the protective layer 1745, a material by which the antenna 1742 can be protected during removal of the separation layer 1701 by etching performed in a later step is used. For example, the protective film 1745 can be formed by application of a water-soluble or alcohol-soluble epoxy-based resin, acrylate-based resin, or silicone-based resin over the entire surface of the third interlayer insulating film 1741.

Next, as shown in FIG. 16B, a groove 1746 is formed in order to separate wireless IC tags into individual devices. The groove 1746 should be formed to a depth such that the separation layer 1701 is exposed. For formation of the groove 1746, dicing, scribing, or the like can be used. It is to be noted that, when there is no need for wireless IC tags formed over the substrate 1700 to be separated up into individual devices, the groove 1746 need not necessarily be formed.

Next, as shown in FIG. 16C, the separation layer 1701 is removed by etching. Here, a halogen fluoride is used as an etching gas, and this gas is introduced from the groove 1746. For example, using chlorine trifluoride (ClF₃), etching is performed under conditions in which the temperature is set to 350° C., the flow rate is set to 300 sccm, the pressure is set to 798 Pa, and the process time is set to 3 hours. Furthermore, a mixed gas of nitrogen mixed into ClF₃ gas may be used, as well. By use of a halogen fluoride gas such as ClF₃ or the like, the separation layer 1701 is etched as selected, and the first substrate 1700 can be separated from the TFTs 1730 to 1732. It is to be noted that the halogen fluoride used here may be either a gas or a liquid.

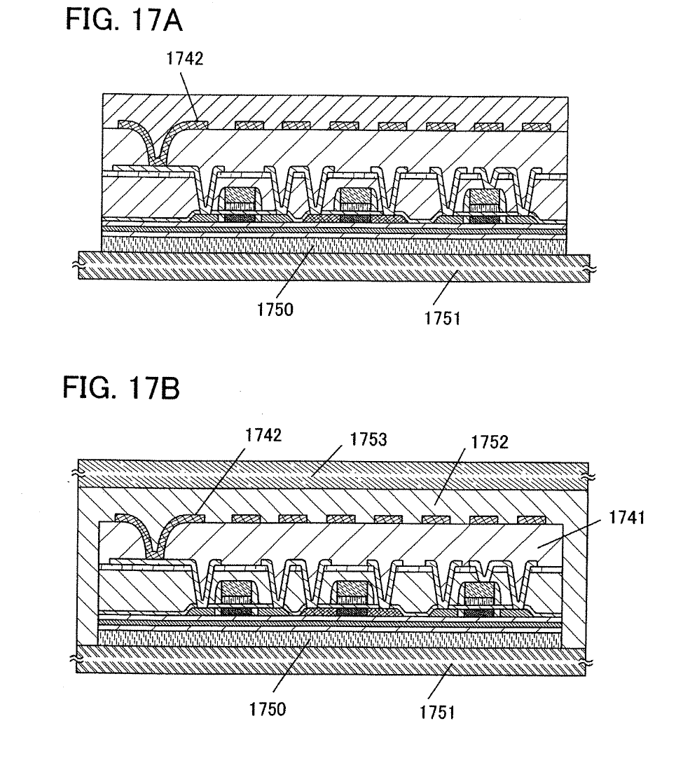

Next, as shown in FIG. 17A, the TFTs 1730 to 1732 and the antenna 1742 that have been separated from the first substrate 1700 are attached to a second substrate 1751 using an adhesive 1750. For the adhesive 1750, a material by which the second substrate 1751 and the base insulating film 1702 can be bonded together is used. For the adhesive 1750, a variety of types of curable adhesives, for example, reactive curable adhesives, thermal curable adhesives, light curable adhesives such as UV curable adhesives or the like, anaerobic adhesives, or the like, can be used.

It is to be noted that, for the second substrate 1751, a flexible organic material of paper, plastic, or the like can be used.

Next, as shown in FIG. 17B, after the protective layer 1745 is removed, an adhesive 1752 is applied over the third interlayer insulating film 1741 so as to cover the antenna 1742, and a cover material 1753 is attached thereto. For the cover material 1753, as with the second substrate 1751, a flexible organic material of paper, plastic, or the like can be used. The thickness of the adhesive 1752 may be, for example, from 10 μm to 200 μm.

Furthermore, the adhesive 1752 can be used to bond the cover material 1753 to the third layer interlayer insulating film 1741 and the antenna 1742. For the adhesive, a variety of types of curable adhesives, for example, reactive curable adhesives, thermal curable adhesives, light curable adhesives such as UV curable adhesives or the like, anaerobic adhesives, or the like, can be used.

By the steps given above, a wireless IC tag can be completed. By the fabrication method described above, an extremely thin integrated circuit with a total film thickness of greater than or equal to 0.3 μm and less than or equal to 3 μm, typically, a total film thickness of about 2 μm, can be formed between the second substrate 1751 and the cover material 1753.

It is to be noted that, in the present embodiment mode, an example is given in which the semiconductor manufacturing apparatus of the present invention is used for the introduction of impurities into a channel formation region; however, the semiconductor manufacturing apparatus of the present invention may be used for the introduction of impurities into an LDD region or into a source region or drain region, as well.

It is to be noted that the thickness of the integrated circuit is not only the thickness of a semiconductor element itself but is to be defined as also including the thicknesses of the various insulating films and interlayer insulating films that are formed between the adhesive 1750 and the adhesive 1752. Furthermore, the area occupied by the integrated circuit that is formed in a wireless IC tag can be made to be about 5 mm or less on each (25 mm² or less), more desirably, from about 0.3 mm on each side (0.09 mm²) to about 4 mm on each side (16 mm²).

It is to be noted that, in the present embodiment mode, a separation method is given in which a separation layer is provided between the first substrate 1700, which is highly resistant to heat, and an integrated circuit, and the substrate and the integrated circuit are separated from each other by removal of the separation layer by etching; however, the fabrication method of a wireless IC tag of the present invention is not to be taken as being limited to having this configuration only. For example, the configuration may be one in which a metal oxide film is provided between a substrate, which is highly resistant to heat, and an integrated circuit, and the integrated circuit is separated from the substrate by weakening of this metal oxide film by crystallization. Alternatively, the configuration may be one in which a separation layer formed by use of an amorphous semiconductor film that contains hydrogen is provided between a substrate, which is highly resistant to heat, and an integrated circuit, and the substrate and the integrated circuit are separated from each other by removal of this separation layer by irradiation with a laser beam. Furthermore, the configuration may be one in which a substrate, which is highly resistant to heat, over which an integrated circuit is formed is eliminated mechanically or removed by etching with a solvent or gas, whereby the integrated circuit may be detached from the substrate.

It is to be noted that, in the present embodiment mode, an example is described which an antenna is formed over the same substrate over which an integrated circuit is formed; however, the present invention is not limited to having only this structure. The structure may be one in which an antenna and an integrated circuit are formed over different substrates and are to be electrically connected to each other by bonding of substrates during a later step.

It is to be noted that the frequencies of electromagnetic waves used in radio frequency identification (RFID), in general, are often 13.56 MHz and 2.45 GHz, and forming wireless IC tags so that electromagnetic waves of these frequencies can be detected is extremely important for increasing versatility.

With the wireless IC tag of the present embodiment mode, there are advantages in that shielding of electromagnetic waves can be reduces more effectively with the wireless IC tags of the present embodiment mode than with RFID formed using semiconductor substrates and attenuation of signals caused by the shielding of electromagnetic waves can be prevented. Consequently, because semiconductor substrates need not necessarily be used, manufacturing costs of the wireless IC tags can be reduced dramatically.

It is to be noted that, in the present embodiment mode, an example was described in which an integrated circuit is separated from the substrate over which it is formed and attached to a substrate that has flexibility; however, the structure of the present invention is not limited to having this kind of structure only. For example, if a substrate that has an allowable temperature limit high enough to withstand heat treatment performed during the fabrication process of the integrated circuit, as with a glass substrate, is used in the IC tag, the integrated circuit need not necessarily be separated from the substrate over which it is formed.

By use of the semiconductor manufacturing apparatus of the present invention, purity can be introduced into a semiconductor film at low concentration and at a high level of accuracy. As a result, variations in threshold voltage of semiconductor devices formed by use of these semiconductor films can be suppressed, and high performance semiconductor devices can be fabricated at high productivity and high yield. Furthermore, because no expensive doping apparatus is used in the introduction of the impurity into the semiconductor film, it becomes possible to provide semiconductor devices at low cost.

### Embodiment Mode 5

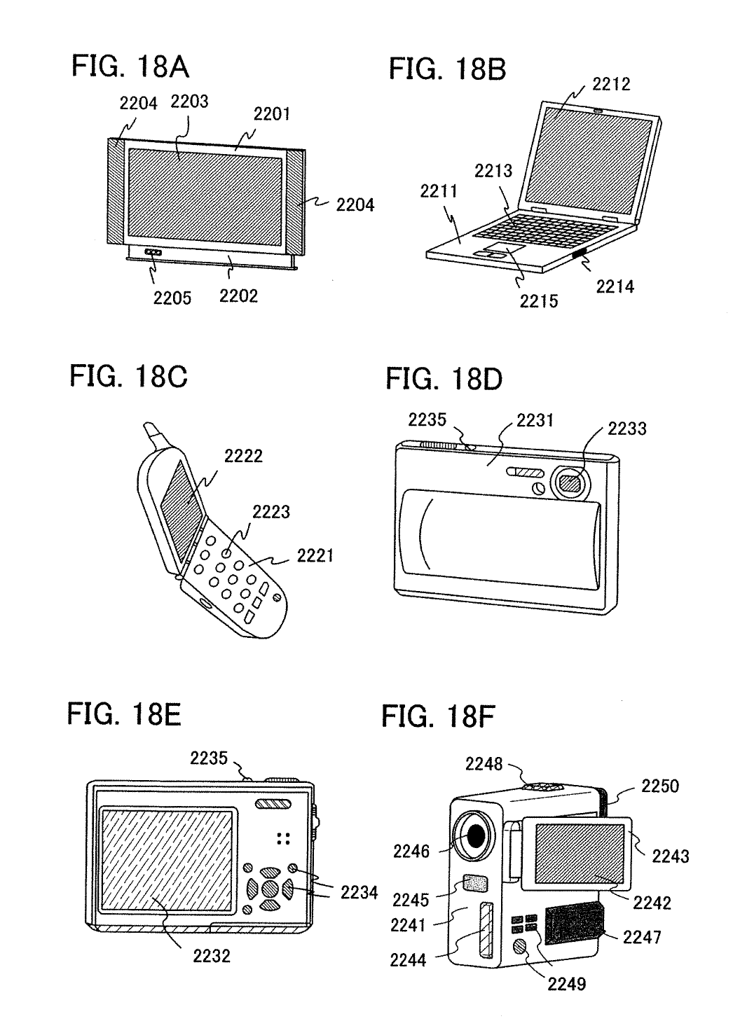

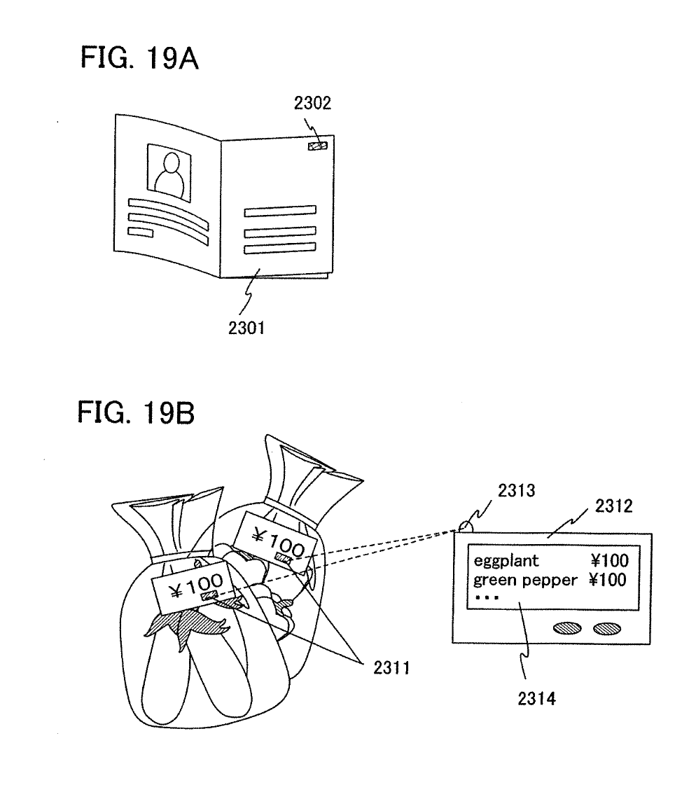

By the present invention, for impurities within a surface of a substrate and between substrates, because an impurity can be introduced into an active layer of a semiconductor element at low concentration and at a high level of accuracy, a high performance semiconductor device can be manufactured at high yield. Furthermore, by use of a semiconductor device of the present invention, an electronic device can be fabricated with good throughput and high quality. Specific examples of these kinds of electronic devices will be described using FIGS. 18A to 18F and FIGS. 19A and 19B. However, the present invention can be implemented in a lot of different modes, and it is to be easily understood by those skilled in the art that various changes and modifications can be made without any departure from the spirit and scope of the present invention. Accordingly, the present invention is not to be taken as being limited to the described content of the embodiment mode included herein.

FIG. 18A is a diagram of a display device that includes a chassis 2201, a support stand 2202, a display 2203, speakers 2204, video input terminals 2205, and the like. The display 2203 is a display in which the pixels are formed of thin film transistors, and the thin film transistors are formed by the same method as that of Embodiment Mode 3. Consequently, impurities can be introduced into a channel formation region of a semiconductor film that is used in each of the thin film transistors at low concentration uniformly, and productivity of the display device can be improved. Furthermore, by use of the present invention, because an impurity can be attached to a plurality of substrates over which a semiconductor film has been formed all at the same time and the amount of the impurity attached to the semiconductor film of each substrate can be controlled efficiently, productivity can be increased dramatically. Consequently, a reduction in production costs for a display device in which thin film transistors are used in the pixels, in particular, production costs for large-screen display devices, can be achieved. In addition, the display device may have memory, a driver circuit section, and the like, and the semiconductor device of the present invention may be applied to the memory, the driver circuit section, and the like. The display device includes various display devices in which thin film transistors and various display media are combined, for example, liquid crystal display devices that use an electro-optic effect of a liquid crystal, display devices that use a luminescent material such as electroluminescence, display devices that use an electron source element, and display devices that a contrast medium (also referred to as electronic ink) the reflectivity of which changes by the application of an electric field. For application modes, all kinds of display devices, such as information display devices for computers, televisions, electronic books, and the like; display devices for advertisement display, information display, and the like; and the like are included.

FIG. 18B is a diagram of a computer that includes a case 2211, a display 2212, a keyboard 2213, an external connection port 2214, a pointing device 2215, and the like. The display 2212 as well as a CPU, memory, a driver circuit section, and the like that are associated with the computer have thin film transistors. By use of thin film transistors fabricated using the semiconductor manufacturing apparatus of the present invention in the display 2212 as well as in a CPU, memory, a driver circuit, and the like that are associated with the computer, product quality can be improved and the amount of variation in product quality can be reduced.

FIG. 18C is a diagram of a cellular phone that is a typical example of a portable terminal. This cellular phone includes a case 2221, a display 2222, operation keys 2223, and the like. The display 2222 as well as functional circuits, such as a CPU, memory, and the like that are associated with the cellular phone have thin film transistors. By use of thin film transistors fabricated using the semiconductor manufacturing apparatus of the present invention in the display 2222 as well as in functional circuits, such as a CPU, memory, and the like that are associated with the cellular phone, quality can be improved and the amount of variation in product quality can be reduced. The semiconductor device that is fabricated using the laser irradiation apparatus of the present invention can be used in electronic devices, including the cellular phone described above as well as personal digital assistants (PDAs, portable information terminals), digital cameras, miniature game machines, and the like.

FIGS. 18D and 18E are diagrams of a digital camera. It is to be noted that FIG. 18E is a diagram of the rear side of the digital camera shown in FIG. 18D This digital camera includes a case 2231, a display 2232, a lens 2233, operation keys 2234, a shutter button 2235, and the like. The display 2232 as well as a driver circuit section, which is used to control the display 2232, and the like have thin film transistors. By use of thin film transistors fabricated using the semiconductor manufacturing apparatus of the present invention in the display 2232 as well as in the driver circuit section that is used to control the display 2232, other circuits, and the like, quality can be improved and the amount of variation in product quality can be reduced.

FIG. 18F is a diagram of a digital video camera. This digital video camera includes a main body 2241, a display 2242, a case 2243; an external connection port 2244, a remote control receiver 2245, an image receiver 2246, a battery 2247, an audio input 2248, operation keys 2249, an eyepiece 2250, and the like. The display 2242 as well as a driver circuit section, which is used to control the display 2242, and the like have thin film transistors. By use of thin film transistors fabricated using the semiconductor manufacturing apparatus of the present invention in the display 2242 as well as in the driver circuit section that is used to control the display 2242, other circuits, and the like, quality can be improved and the amount of variation in product quality can be reduced.

In addition, the thin film transistors fabricated using the laser irradiation apparatus of the present invention can be used as thin film integrated circuits or contactless thin film integrated circuit devices (also referred to as wireless IC tags and radio frequency identification (RFID, wireless authentication)). Thin film integrated circuits and contactless thin film integrated circuit devices fabricated using fabrication methods given in other embodiment modes can be used in tags and memory.

In FIG. 19A, a case in which a wireless IC tag 2302 is attached to a passport 2301 is shown. Additionally, the wireless IC tag 2302 may also be embedded in the passport 2301. In the same way, a wireless IC tag may be attached to or embedded in driver's licenses, credit cards, paper currency, coins, bonds, gift certificates, tickets, traveler's checks (T/C), health insurance cards, resident's cards, copies of family registers, and the like. In each of these cases, only data indicating that the object is authentic is input to the wireless IC tag, and access rights can be set so that unauthorized reading out and writing of data cannot be performed. By use of a tag in this way, differentiating authentic objects from counterfeit ones becomes possible.

In addition, a wireless IC tag can be used as memory. In FIG. 19B, an example in which a wireless IC tag 2311 is embedded in a label that is attached to the wrapping of a vegetable is shown. Moreover, a wireless IC tag may also be attached to or embedded in the wrapping itself. In the wireless IC tag 2311, place of origin, producer, date of production, processes of the production stage such as process methods and the like, product distribution processes, price, quantity, intended application, shapes and forms, weight, expiration date, various types of authentication information, and the like can be stored. Data from the wireless IC tag 2311 is received by and read out by an antenna 2313 of a wireless reader 2312 and displayed on a display 2314 of the reader 2312, whereby wholesalers, distributors, and consumers can easily obtain the information. By access rights of each producer, trader, and consumer being set, a system can be set up in which those consumers that do not have authority to access the data cannot read, write, rewrite, or erase the data.

Furthermore, the wireless IC tag can be used as described hereinafter. In accounting, at the time of payment, information relating that payment has been made is written to the wireless IC tag, and whether payment has been made or not is checked by a checking device provided at an exit that checks to see if the information that payment has been made has been written to the wireless IC tag. If the wireless IC tag is taken out of the store without payment having been made, an alarm rings. With this method, payment being forgotten to be made and shoplifting can be prevented.

In consideration of protection of customer privacy, the following method can also be used. In payment at a cash register, any of the following may be conducted: (1) data input to the wireless IC tag is locked by a pin number or the like; (2) the data itself that is input to the wireless IC tag is encrypted; (3) data input to the wireless IC tag is erased; and (4) data input to the wireless IC tag is destroyed. Then, a checking device that is provided at an exit checks to see if any one of the processes of (1) to (4) has been conducted or if the data in the wireless IC tag has not been processed so that whether the payment has been made or not is checked. In this way, whether the payment has been made or not can be checked in the store, and reading out of the information in the wireless IC tag outside the store against the will of the possessor of the wireless IC tag can be prevented.

Several methods can be given for destruction of the data that is input to the wireless IC tag in (4). For example, (a) only the data is destroyed by writing of either one or both of “0” (“off”) and “1” (“on”) in at least a part of the electronic data in the wireless IC tag or (b) a current is made to flow excessively through the wireless IC tag so that a part of a wiring included in a semiconductor element in the wireless IC tag is destroyed.

Because manufacturing costs of these wireless IC tags that are described above are higher than those of barcodes used conventionally, there is a need for a reduction in costs. According to the present invention, however, because uniform laser annealing of a semiconductor film is possible, semiconductor devices with favorable product quality and no variation can be manufactured effectively, which is effective for a reduction in costs. Furthermore, any wireless IC tag can be manufactured so as to be highly reliable and to have high product quality with no variation in performance.

As thus described, the range of application for a semiconductor device manufactured by use of the present invention is extremely wide, and a semiconductor device that is manufactured by use of the present invention can be applied to electronic devices of any field.

### Embodiment 1

Hereinafter, even more detailed descriptions of embodiments of the present invention will be given; however, the present invention is not to be taken as being limited to these embodiments, and it goes without saying that the present invention is to be specified by the range of the patent claims given.

In the present embodiment, results of an experiment in which a crystalline semiconductor film that contains an impurity at low concentration was formed over a substrate according to the fabrication steps given in Embodiment Mode 1 are shown.

For the substrate, a glass substrate with a thickness of 0.7 mm, manufactured by Corning Incorporated, was used. Furthermore, for a base insulating film, a stacked-layer structure of a silicon nitride oxide film and a silicon oxynitride film was used, and each of the films was formed in a parallel-plate CVD plasma apparatus. Specifically, the substrate was heated to a temperature of 300° C.; for film formation gases (flow rates), SiH₄ (10 sccm), NH₃ (100 sccm), N₂O (20 sccm), and H₂ (400 sccm) were made to flow at a pressure of 40 Pa; and a plasma was formed with RF power at an RF frequency of 27 MHz set to be 50 W and the distance between electrodes set to be 30 mm, whereby the silicon nitride oxide film was formed at a film thickness of 50 nm.

Subsequently, the substrate over which the silicon nitride oxide film was formed was moved to a different process chamber and heated to a temperature of 400° C.; for film formation gases (flow rates), SiH₄ (4 sccm) and N₂O (800 sccm) were made to flow at a pressure of 40 Pa; and a plasma was formed with RF power at an RF frequency of 27 MHz set to be 50 W and the distance between electrodes set to be 15 mm, whereby the silicon oxynitride film was formed at a film thickness of 100 nm.

Next, over the base insulating film, for a semiconductor film, an amorphous silicon film was formed in a parallel-plate CVD plasma apparatus. Specifically, the substrate was heated to a temperature of 250° C.; for film formation gases (flow rates), SiH₄ (25 sccm) and H₂ (150 sccm) were made to flow at a pressure of 66.7 Pa; and a plasma was formed with RF power at an RF frequency of 27 MHz set to be 50 W and the distance between electrodes set to be 25 mm, whereby a silicon nitride oxide film was formed at a film thickness of 66 nm.

After the amorphous semiconductor film was formed under the film formation conditions given above, the substrate over which the amorphous semiconductor film was formed was heated to a temperature of 500° C. in an electric furnace for one hour for performance of dehydrogenation treatment.

Then, the substrate over which an oxide film layer that is not needed was formed by heat treatment at the time that the semiconductor film layer was formed or dehydrogenation treatment was performed or was formed over the semiconductor film at the time that the substrate was transported was transferred to the prewashing unit, which is used for removal of impurities, of the semiconductor manufacturing apparatus of the present invention. For the prewashing unit that is used for removal of impurities, after the oxidized film layer was removed by rotation of the washing machine while 0.5 wt % of fluoric acid was being discharged for 70 seconds using a sheet-fed spin washing machine, the substrate was washed with water that contains CO₂, an oxide film was formed over the surface of the semiconductor film and the substrate rotated and dried while ozonated water was being discharged for 40 seconds.

Next, the substrate was transferred to the impurity introduction unit. For the impurity introduction method, the substrate was left in the process chamber for two hours during which 5% B₂H₆ gas diluted with hydrogen was made to flow at a rate of 30 sccm and boron was attached over the surface of the amorphous semiconductor film.

Next, the substrate was transferred to the laser crystallization unit. Here, for a laser oscillator, the second harmonic (532 nm) of a YVO₄ pseudo continuous wave mode-locked laser where output was 20 W and the oscillation mode was TEM₀₀ with a repetition rate of 80 MHz±1 MHz was used. Furthermore, a linear laser beam with a laser beam with a width of approximately 500 μm along the long axis and a width of approximately 20 μm along the short axis was formed with an optical system. Then, the substrate was placed on a stage that has x and y axes; while the stage was moved in the x-axis direction, which is to be the direction along the short axis of the linear laser beam, at a speed of 350 mm/s, the substrate was irradiated linearly with the linear laser beam from edge to edge; the stage was moved 500 μm, which is to be the width of the long axis of the linear laser beam, in the y-axis direction, which is to be the direction along the long axis of the linear laser beam; and while the stage was moved in the x-axis direction in a direction differing from the previous direction by 180°, at a speed of 350 mm/s, the substrate was irradiated linearly with the linear laser beam from edge to edge, in the same way. In this way, by the substrate being irradiated back and forth with the linear laser beam, laser crystallization was performed over the entire surface of the substrate.

It is to be noted that, with the optical system used to form the laser beam into the linear laser beam, after a laser beam emitted from a laser oscillator was transmitted through an attenuator that can be used to change the transmittance of the laser beam and the beam size of the laser beam is doubled by a beam expander, the long axis direction of the laser beam was shielded using a slit with a width of 1 mm. Then, after the laser beam was transmitted through a long-axis cylindrical lens, which was arranged so that the image of the long axis direction of the laser beam immediately after passing through the slit was reduced and transcribed so as to be approximately 500 μm wide on the surface that was to be irradiated, and the direction in which the laser beam progresses was changed to the direction of incident light using an incident-light mirror, the width of the short axis on the surface that was to be irradiated was adjusted so as to be approximately 20 μm by a short-axis cylindrical lens, whereby a linear laser beam was formed such that the width of the long axis on the surface that was to be irradiated was approximately 500 μm and the short axis thereon was approximately 20 μm.

In the laser crystallization process described above, an amorphous silicon film was irradiated with the linear laser beam and melted at the same time as boron was diffused throughout the melted silicon film. That is, at the same time as the melted silicon film was crystallized, boron was activated at a high activation rate, and a polycrystalline silicon film that contains boron at a low concentration was formed.

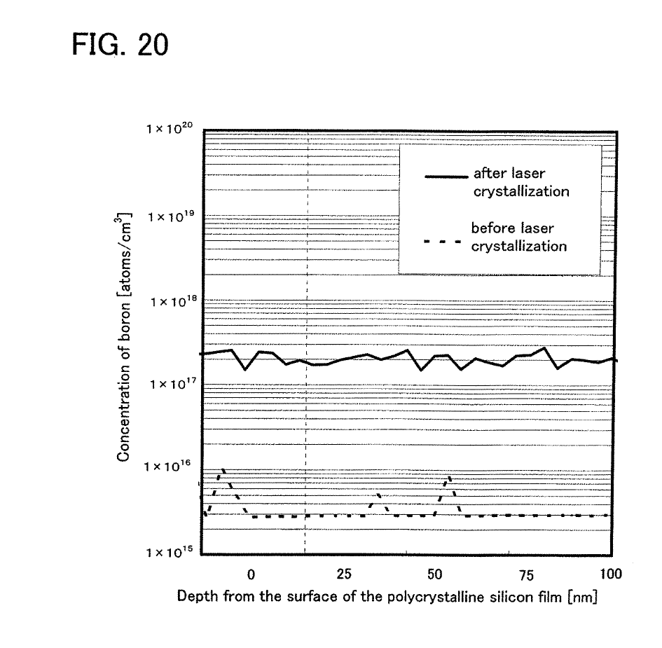

Results of the concentration of boron introduced throughout the polycrystalline silicon film that were measured using secondary ion mass spectrometry (SIMS) are shown in FIG. 20. In FIG. 20, the concentration (atoms/cm³) of boron introduced is given on the vertical axis, and the depth (nm) from the surface of the polycrystalline silicon film is given on the horizontal axis.

It is to be noted that, because measurement accuracy of concentration within a film cannot be obtained if the thickness of the object to be measured is thin, in consideration of measurement accuracy, measurements were taken using a substrate formed of an amorphous silicon film that was formed at a thickness of 100 nm as a monitor substrate. The measured concentration of boron throughout the polycrystalline silicon film was approximately 2×10¹⁷ atoms/cm³, and it was confirmed that approximately the same concentration of boron could be introduced as when conventional channel doping was used, with a desired threshold voltage of 0.9 V.

Furthermore, the concentration of boron dispersed throughout the polycrystalline silicon film was introduced approximately uniformly with respect to the direction of depth from the surface. In addition, it was shown that because boron was not introduced throughout the amorphous silicon film in the case in which laser crystallization was not performed, boron was introduced throughout the semiconductor film by the laser crystallization step.

By the results given above, it was shown that introduction of an impurity into an active layer at low concentration as well as at approximately uniform concentration can be realized with good productivity by use of the semiconductor manufacturing apparatus of the present invention.

### Embodiment 2

In the present embodiment, results of an experiment in which, in the impurity introduction unit of the semiconductor manufacturing apparatus of the present invention, an impurity was generated using a chemical solution and an FFU and exposed in a stocker will be described.

First, a silicon nitride oxide film with a film thickness of 50 nm and a silicon oxynitride film with a film thickness of 100 nm were stacked together as a base insulating layer over a glass substrate, and an amorphous silicon film with a film thickness of 66 nm was formed over the base insulating film as an amorphous semiconductor film by a plasma CVD method. Next, after heat treatment was performed at 500° C. for one hour for dehydrogenation treatment, heat treatment was performed at 550° C. for four hours, the substrate was treated with 0.5 vol. % HF for 90 seconds using the sheet-fed spin washing machine in the prewashing unit before the introduction of impurities, and a silicon oxide film and impurities formed over the amorphous silicon film were removed. Subsequently, in a boron atmosphere in which a filter that contains boron was used for the filter of the FFU unit of the impurity introduction unit, the substrate was exposed for 24 hours using the stocker, and boron was attached over the amorphous silicon film.

Next, in the laser crystallization unit, laser crystallization was performed using a pseudo continuous wave laser, and boron was introduced into the silicon film while a polycrystalline silicon film was formed at the same time. Here, for the laser crystallization method, the entire surface of the substrate was irradiated with the laser beam under the same conditions as the conditions outlined in Embodiment 1.

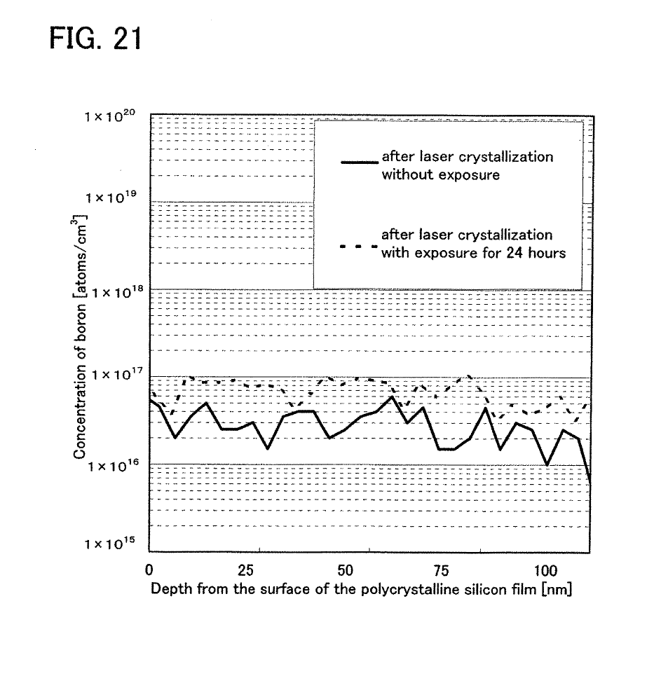

In FIG. 21, SIMS measurement results of the concentration of boron in the polycrystalline silicon film after laser crystallization has been performed are shown. Furthermore, as a reference, SIMS measurement results of the concentration of boron in a polycrystalline silicon film of a substrate that has been crystallized by laser crystallization where the substrate has not been exposed to the boron atmosphere after removal of the silicon oxide film are shown. It is to be noted that, in FIG. 21, the concentration (atoms/cm³) of boron introduced is given on the vertical axis, and the depth (nm) from the surface of the polycrystalline silicon film is given on the horizontal axis.

For the case in which the substrate was not exposed to the boron atmosphere, a concentration of boron of approximately 2×10¹⁶ atoms/cm³ was introduced into the polycrystalline silicon film. Moreover, for the case in which the substrate was exposed to the boron atmosphere for 24 hours, a concentration of boron of approximately 9×10¹⁶ atoms/cm³ was introduced into the polycrystalline silicon film. From these results, it could be seen that the concentration of boron introduced into the polycrystalline silicon film could be controlled even at a low concentration by exposure of the substrate to the boron atmosphere.

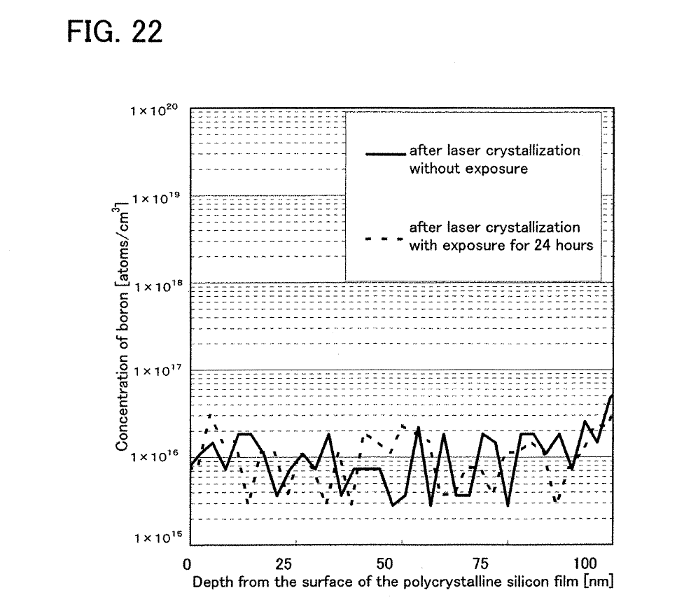

Furthermore, in the FFU, measurement results of the amount of boron introduced in the case in which a boronless filter and a chemical filter were employed instead of a filter that contains boron are shown in FIG. 22. It is to be noted that conditions other than those of the filter in the FFU were the same as those for FIG. 21. In FIG. 22, the concentration of boron introduced into the polycrystalline silicon film came to be a value close to the minimum limit of detection of approximately 1×10¹⁶ atoms/cm³ or less, regardless of the length of time of exposure to the impurity introduction unit. From these results, it was shown that the boron introduced into the polycrystalline silicon film for FIG. 21 originated with the filter that contains boron of the FFU. In addition, it was shown that whether there is any scattering of boron in the atmosphere of the unit or not can be controlled by proper use of filters as appropriate.

Moreover, after laser crystallization, a resist was applied over the polycrystalline silicon film that was formed, the resist was exposed to light and developed so that the resist was formed into a given shape, etching was performed using the formed resist as a mask, and island-shaped polycrystalline semiconductor films were formed. A TFT was formed using these island-shaped polycrystalline semiconductor films.

It is to be noted that the shape of a channel in the polycrystalline semiconductor film was set with the channel length being 1 μm and the channel width being 8 μm. Furthermore, phosphorus or boron was introduced into respective source regions or drain regions in the island-shaped polycrystalline semiconductor films by an ion doping apparatus, and a plurality of n-channel TFTs and p-channel TFTs was formed.

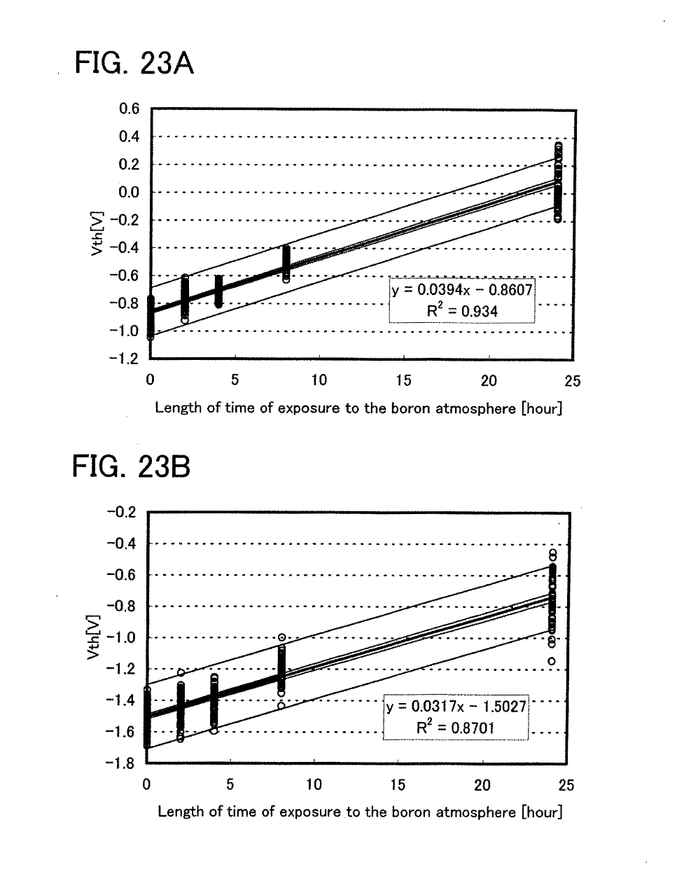

Results of an examination by regression analysis of a correlation between the threshold voltage Vₜₕ and the length of time of exposure to the boron atmosphere of n-channel TFTs that were formed are shown in FIG. 23A. Furthermore, results of an examination by regression analysis of a correlation between the threshold voltage Vₜₕ and the length of time of exposure to the boron atmosphere of p-channel TFTs that were formed are shown in FIG. 23B. It is to be noted that measurement conditions were set so that drain voltage V_{D}=3 V.

In FIG. 23A, threshold voltage (V) for the n-channel TFTs is given on the vertical axis, and the length of time (hour) of exposure of the substrate to the boron atmosphere of the impurity introduction unit is given on the horizontal axis. From FIG. 23A, it can be seen that there is a proportional relationship between threshold voltage of the n-channel TFTs and the length of time of exposure of the substrate to the boron atmosphere of the impurity introduction unit. It is to be noted that, in FIG. 23A, for the n-channel TFTs, as the length of time of exposure was increased, the threshold voltage increased at a ratio of approximately 0.04 V per hour.

Moreover, in FIG. 23B, threshold voltage (V) for the p-channel TFTs is given on the vertical axis, and the length of time (hour) of exposure of the substrate to the boron atmosphere of the impurity introduction unit is given on the horizontal axis. From FIG. 23B, it can be seen that there is a proportional relationship between threshold voltage of the p-channel TFTs and the length of time of exposure of the substrate to the boron atmosphere of the impurity introduction unit. It is to be noted that, in FIG. 23B, for the p-channel TFTs, as the length of time of exposure was increased, the threshold voltage increased at a ratio of approximately 0.03 V per hour.

From the results of FIGS. 23A and 23B, it was shown that threshold voltage could be controlled easily and with a high level of accuracy by use of the semiconductor manufacturing apparatus of the present invention. In the present embodiment, the absolute value of the threshold voltage was low for the actual operating value; however, by either extending the length of the exposure time of the substrate to the boron atmosphere or increasing the concentration of boron in the boron atmosphere, the threshold voltage of a semiconductor element can be controlled. Moreover, because the concentration of impurity introduced into the semiconductor film is low for a certain exposure time, the concentration of impurity introduced into the semiconductor film can be controlled with a high level of accuracy even if there are slight variations in the length of the exposure time.

### Embodiment 3

In the present embodiment, results of an experiment in which, in the impurity introduction unit of the semiconductor manufacturing apparatus of the present invention, a substrate was exposed to an impurity atmosphere that was generated using tri-n-octyl borate, which is an ester borate compound, as the chemical solution will be described.

First, a silicon nitride oxide film with a film thickness of 50 nm and a silicon oxynitride film with a film thickness of 100 nm were stacked together as a base insulating layer over a glass substrate, and an amorphous silicon film with a film thickness of 150 nm was formed over the base insulating film as an amorphous semiconductor film by a plasma CVD method. Next, dehydrogenation treatment was performed, the substrate from which a silicon oxide film and impurities formed over the amorphous silicon film were removed in the prewashing unit before the introduction of impurities was exposed for 5 minutes to a boron atmosphere that was generated by hydrolysis of tri-n-octyl borate, and boron was attached over the amorphous silicon film.

Next, in the laser crystallization unit, laser crystallization was performed using a pseudo continuous wave laser, and boron was introduced into the silicon film while a polycrystalline silicon film was formed at the same time. Here, for the laser crystallization method, the entire surface of the substrate was irradiated with the laser beam under the same conditions as the conditions outlined in Embodiment 1.

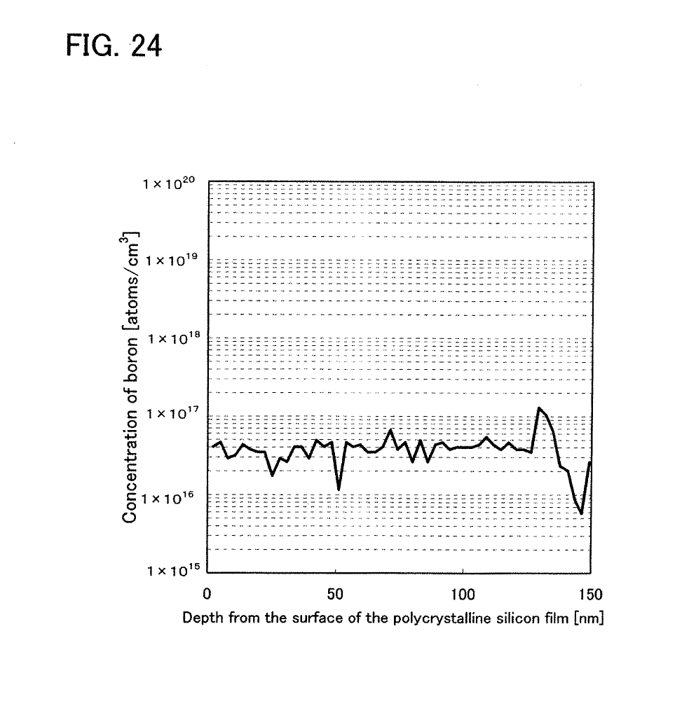

In FIG. 24, SIMS measurement results of the concentration of boron in the polycrystalline silicon film after laser crystallization has been performed are shown. It is to be noted that, in FIG. 24, the concentration (atoms/cm³) of boron introduced is given on the vertical axis, and the depth (nm) from the surface of the polycrystalline silicon film is given on the horizontal axis. By FIG. 24, it was shown that boron was introduced into the polycrystalline silicon film at a concentration of approximately 3×10¹⁶ atoms/cm³ and that the concentration of boron introduced into the polycrystalline silicon film could be controlled even at a low concentration by exposure of the substrate to the boron atmosphere that was generated using tri-n-octyl borate.

This application is based on Japanese Patent Application serial no. 2007-057424 filed with the Japan Patent Office on Mar. 7, 2007, the entire contents of which are hereby incorporated by reference.

What is claimed is:

1. A method of manufacturing a semiconductor device comprising the steps of:
forming a semiconductor film over a substrate;
transporting the substrate into a first unit, wherein the first unit includes an impurity atmosphere so that an impurity is attached to a surface of the semiconductor film;
transporting and mounting the substrate to which the impurity is attached over a stage in a second unit;
irradiating the semiconductor film over the stage with a laser beam that is projected from a laser oscillator in the second unit in order to crystallize the semiconductor film to which the impurity is attached so that a crystalline semiconductor film that contains the impurity is formed.

2. The method of manufacturing a semiconductor device according to claim 1,
wherein the impurity atmosphere contains an element belonging to group 13 or group 15 of the periodic table of the elements.

3. The method of manufacturing a semiconductor device according to claim 1,
wherein a concentration of the impurity contained in the crystalline semiconductor film contains is in a range of 1×10¹⁵ atoms/cm³ to 1×10¹⁸ atoms/cm³.

4. The method of manufacturing a semiconductor device according to claim 1, further comprising the steps of:
washing the surface of the semiconductor film after forming the semiconductor film; and
forming an oxide film over the semiconductor film after washing the surface of the semiconductor film.

5. The method of manufacturing a semiconductor device according to claim 1,
wherein the first unit and the second unit are provided independently from each other.

6. A method of manufacturing a semiconductor device comprising the steps of:
forming a semiconductor film over a substrate;
washing a surface of the semiconductor film;
transporting the substrate into an impurity atmosphere after washing the surface of the semiconductor film so that an impurity is attached to the surface of the semiconductor film;
transporting and mounting the substrate to which the impurity is attached over a stage;
irradiating the semiconductor film over the stage with a laser beam that is projected from a laser oscillator in order to crystallize the semiconductor film to which the impurity is attached so that a crystalline semiconductor film that contains the impurity is formed.

7. The method of manufacturing a semiconductor device according to claim 6,
wherein the impurity atmosphere contains an element belonging to group 13 or group 15 of the periodic table of the elements.

8. The method of manufacturing a semiconductor device according to claim 6,
wherein a concentration of the impurity contained in the crystalline semiconductor film contains is in a range of 1×10¹⁵ atoms/cm³ to 1×10¹⁸ atoms/cm³.

9. The method of manufacturing a semiconductor device according to claim 6, further comprising the step of forming an oxide film over the semiconductor film after washing the surface of the semiconductor film.

10. A method of manufacturing a semiconductor device comprising the steps of:
forming a semiconductor film over a substrate;
washing a surface of the semiconductor film;
transporting the substrate into an impurity atmosphere after washing the surface of the semiconductor film so that an impurity is attached the surface of the semiconductor film, wherein an amount of the impurity that is attached to the semiconductor film is controlled by a length of time of exposure to the impurity;
transporting and mounting the substrate to which the impurity is attached over a stage;
irradiating the semiconductor film over the stage with a laser beam that is projected from a laser oscillator in order to crystallize the semiconductor film to which the impurity is attached so that a crystalline semiconductor film that contains the impurity is formed.

11. The method of manufacturing a semiconductor device according to claim 10,
wherein the impurity atmosphere contains an element belonging to group 13 or group 15 of the periodic table of the elements.

12. The method of manufacturing a semiconductor device according to claim 10,
wherein a concentration of the impurity contained in the crystalline semiconductor film contains is in a range of 1×10¹⁵ atoms/cm³ to 1×10¹⁸ atoms/cm³.

13. The method of manufacturing a semiconductor device according to claim 10, further comprising the step of forming an oxide film over the semiconductor film after washing the surface of the semiconductor film.
